(19) United States
(12) Patent Application Publication
(10) Pub. No.: US 2022/0250933 A1
(43) Pub. Date: Aug. 11, 2022

(54) METHOD FOR STABILIZATION OF ZINC OXIDE NANOPARTICLES

(71) Applicant: NANOSYS, INC., Milpitas, CA (US)

(72) Inventors: Christian IPPEN, Cupertino, CA (US); Emma Rose DOHNER, Redwood City, CA (US); Ruiqing MA, Morristown, NJ (US)

(73) Assignee: NANOSYS, INC., Milpitas, CA (US)

(21) Appl. No.: 17/617,685

(22) PCT Filed: Jun. 11, 2020
(86) PCT No.: PCT/US2020/037173

§ 371 Date: Dec. 9, 2021

Related U.S. Application Data
(60) Provisional application No. 62/861,010, filed on Jun. 13, 2019.

(51) Int. Cl. C01G 9/02; H01L 51/50; H01L 51/42; H01L 33/06

(52) U.S. Cl. CPC C01G 9/02; H01L 51/502; B82Y 20/00; H01L 33/06; H01L 51/4233

(57) ABSTRACT

This invention pertains to the field of nanotechnology. The invention relates to nanoparticles comprising zinc oxide treated with a silane compound. The nanoparticles comprising zinc oxide functionalized with silane compounds show improved stability. And, quantum dot light emitting diodes prepared using nanoparticles comprising zinc oxide functionalized with silane compounds in the electron transport layer show improved per-formance. The invention also relates to methods of producing nanoparticles comprising zinc oxide functionalized with silane compounds.

### BACKGROUND OF THE INVENTION

### Field of the Invention

This disclosure pertains to the field of nanotechnology. The disclosure provides nanoparticles comprising zinc oxide functionalized with silane compounds. The nanoparticles comprising zinc oxide functionalized with silane compounds show improved stability. And, quantum dot light emitting diodes prepared using nanoparticles comprising zinc oxide functionalized with silane compounds in the electron transport layer show improved performance. The disclosure also provides methods of producing nanoparticles comprising zinc oxide functionalized with silane compounds.

### Background Art

Zinc oxide (ZnO) and zinc magnesium oxide (ZnMgO) nanoparticles are used advantageously as solution-processable electron transporting materials in quantum dot light emitting diodes (QD-LEDs). Silane treatments on oxide materials have been applied to ZnO nanoparticles to improve their stability in water (Matsuyama, K., et al., J. Colloid and Interface Science 339:19-25 (2013)), to provide tunable white light emission (Layek, A., et al., Chem. Mater. 27(3):1021-1030 (2015)), to increase their compatibility with polymers (Huang, H. C., et al., Ceramics International 36(4):1245-1251 (2010); and Soumaya, S., Solar Energy Materials and Solar Cells 174:554-565 (2018)), and as a linker between ZnO electron transport layers and active layers in polymer solar cells (Fu, P., et al., ACS Appl. Mater. Interfaces 9(15):13390-13395 (2017)). Functional groups such as 3-methacryloxypropyl-trimethoxysilane, 3-aminopropyltriethoxysilane, and 3-glycidyloxypropyltrimethoxysilane have been applied to ZnO—with the functional groups used for binding to another entity or for reacting with a monomer (Kotecha, M., et al., Microporous and Mesoporous Materials 95(1-3):66-75 (2006)); and Y. Yoshioka, J. Polymer Science: Part A 47(19):4908-4918 (2009)).

ZnO nanoparticles have been prepared using a sol-gel chemical route. The sol-gel synthesis involves the hydrolysis of metal carboxylate salts followed by condensation of metal hydroxide to metal oxide. The surface of these metal oxide particles comprises residual hydroxy groups, which can continue to condense with hydroxy groups on the same or on other particles.

Condensation of the hydroxy groups on these nanoparticles results in a red shift in the absorption spectra (FIG. 1), because an increase in particle size or exciton delocalization over aggregated particles lowers the blue-shifting effect of quantum confinement. This change in band gap alters the band alignment in QD-LEDs and can impact device performance. For example, blue-emitting QD-LEDs show lower external quantum efficiency (EQE) after ZnMgO has been stored for several days (FIG. 2). In extreme cases, the continued condensation of the hydroxy groups can lead to a loss of colloidal stability (gel formation), which can make these nanoparticles unusable for solution-processing.

The condensation of ZnMgO nanoparticles caused by long storage periods can be suppressed by storing the nanoparticles at very low temperatures (−45° C. or lower). But, low temperature storage is impractical for logistical reasons and for device manufacturing. Further, ethanolamine is often added as a stabilizing ligand. Addition of ethanolamine to ZnMgO nanoparticles prevents loss of colloidal stability. But, a red shift in absorption spectra is still observed. And, ZnMgO nanoparticles containing ethanolamine can cause a change in device performance that can be even more dramatic than observed in devices prepared with ZnMgO nanoparticles which do not contain an added ligand. Ethanolamine only binds weakly and it is volatile; therefore, it can detach during the device process and affect other materials in the device layers.

A need exists to prepare nanoparticles comprising zinc oxide that have improved stability and do not show a negative effect on device performance.

### BRIEF SUMMARY OF THE INVENTION

The present disclosure provides a nanoparticle composition, comprising:

(a) at least one population of nanoparticles comprising a zinc oxide; and

(b) at least one silane compound bound to the surface of the nanoparticles; wherein the nanostructure composition is stable for at least 7 days when stored at room temperature.

In some embodiments, the nanoparticles comprising a zinc oxide are doped with at least one dopant.

In some embodiments, the nanoparticles comprising a zinc oxide are doped with at least one dopant selected from the group consisting of lithium, boron, carbon, nitrogen, fluorine, sodium, aluminum, silicon, chlorine, potassium, scandium, titanium, vanadium, chromium, manganese, nickel, gallium, arsenic, palladium, gold, cadmium, indium, tin, antimony, lead, and combinations thereof.

In some embodiments, the nanoparticles comprising a zinc oxide are alloyed with at least one metal ion.

In some embodiments, the nanoparticles comprising a zinc oxide are alloyed with magnesium.

In some embodiments, the at least one silane compound has the formula:

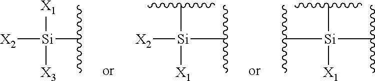

wherein:

X₁ is straight or branched C₁₋₂₀ alkyl;

X₂ is straight or branched C₁₋₂₀ alkyl or straight or branched C₁₋₂₀ alkoxy; and

X₃ is straight or branched C₁₋₂₀ alkyl or straight or branched C₁₋₂₀ alkoxy; wherein at least one of X₁, X₂, and X₃ is a straight or branched C₁₋₂₀ alkyl.

In some embodiments, X₁ is a straight C₁₋₂₀ alkyl and X₂ and X₃ are straight C₁₋₂₀ alkoxy.

In some embodiments, X₁ and X₂ are straight C₁₋₂₀ alkyl and X₃ is a straight C₁₋₂₀ alkoxy.

In some embodiments, the at least one silane compound is selected from the group consisting of dimethoxymethylsilyl-, diethoxymethylsilyl-, dipropoxymethylsilyl-, dibutoxymethylsilyl-, methoxydimethylsilyl-, ethoxydimethylsilyl-, dimethoxydodecylsilyl-, methoxydodecylmethylsilyl-, dimethoxyhexadecylsilyl-, dimethoxyoctadecylsilyl-, dimethoxy(n-octyl)silyl-, diethoxy(n-octyl)silyl-, ethoxyoctylmethylsilyl-, dimethoxypropylsilyl-, diethoxypropylsilyl-, dimethoxy(n-butyl)silyl-, diethoxy(n-butyl)silyl-, dimethoxy(i-butyl)silyl-, and diethoxy(i-butyl)silyl-.

In some embodiments, the at least one silane compound is dimethoxymethylsilyl-.

In some embodiments, the nanoparticle composition is stable for at least 14 days when stored at room temperature.

In some embodiments, the nanoparticle composition is stable for at least 1 month when stored at room temperature.

In some embodiments, an illumination device is prepared comprising the nanoparticle composition described herein.

In some embodiments the illumination device is a light emitting diode.

The present disclosure also provides a method of preparing a nanoparticle composition, the method comprising:

(a) admixing a reaction mixture comprising a population of nanoparticles comprising a zinc oxide having at least one hydroxy group covalently bound to the nanoparticle with at least one silane; and

(b) adding a reactant comprising water, a base, or a combination thereof to the reaction mixture in (a).

In some embodiments, the nanoparticles comprising a zinc oxide are doped with at least one dopant.

In some embodiments, the nanoparticles comprising a zinc oxide are doped with at least one dopant selected from the group consisting of lithium, boron, carbon, nitrogen, fluorine, sodium, aluminum, silicon, chlorine, potassium, scandium, titanium, vanadium, chromium, manganese, nickel, gallium, arsenic, palladium, gold, cadmium, indium, tin, antimony, lead, and combinations thereof.

In some embodiments, the nanoparticles comprising a zinc oxide are alloyed with at least one metal ion.

In some embodiments, the nanoparticles comprising a zinc oxide are alloyed with magnesium ion.

In some embodiments, the at least one silane has the formula:

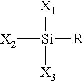

wherein:

R is a straight or branched C₁₋₂₀ alkoxy;

X₁ is straight or branched C₁₋₂₀ alkyl or straight or branched C₁₋₂₀ alkoxy;

X₂ is straight or branched C₁₋₂₀ alkyl or straight or branched C₁₋₂₀ alkoxy; and

X₃ is straight or branched C₁₋₂₀ alkyl or straight or branched C₁₋₂₀ alkoxy; wherein at least one of X₁, X₂, and X₃ is a straight or branched C₁₋₂₀ alkyl.

In some embodiments, X₁ is a straight C₁₋₂₀ alkyl and X₂ and X₃ are straight C₁₋₂₀ alkoxy.

In some embodiments, X₁ and X₂ are straight C₁₋₂₀ alkyl and X₃ is a straight C₁₋₂₀ alkoxy.

In some embodiments, the at least one silane is selected from the group consisting of trimethoxymethylsilane, triethoxymethylsilane, tripropoxymethylsilane, tributoxymethylsilane, dimethoxydimethylsilane, diethoxydimethylsilane, trimethoxydodecylsilane, dimethoxydodecylmethylsilane, trimethoxyhexadecylsilane, trimethoxyoctadecylsilane, trimethoxy(n-octyl)silane, triethoxy(n-octyl)silane, diethoxyoctylmethylsilane, trimethoxypropylsilane, triethoxypropylsilane, trimethoxy(n-butyl)silane, triethoxy(n-butyl)silane, trimethoxy(i-butyl)silane, and triethoxy(i-butyl)silane.

In some embodiments, the at least one silane is trimethoxymethylsilane.

In some embodiments, the admixing in (a) is performed at a temperature between about 0° C. and about 200° C.

In some embodiments, the admixing in (a) is performed at a temperature between about 10° C. and about 30° C.

In some embodiments, the admixing in (a) is performed at a temperature between about 20° C. and about 25° C.

In some embodiments, the admixing in (a) is performed over a period of about 1 minute and about 6 hours.

In some embodiments, the admixing in (a) is performed over a period of about 1 minute and 2 hours.

In some embodiments, the ratio of silanes to the number of Zn surface atoms is between about 2 equivalents and about 10 equivalents.

In some embodiments, the ratio of silanes to the number of Zn surface atoms is between about 3 equivalents and about 6 equivalents.

In some embodiments, the ratio of silanes to the number of Zn surface atoms is about 5 equivalents.

In some embodiments, the reactant added in (b) comprises water.

In some embodiments, water is the only reactant added in (b).

In some embodiments, the reactant added in (b) comprises a base.

In some embodiments, a base is the only reactant added in (b).

In some embodiments, the reactant added in (b) comprises a base selected from the group consisting of acetone, ammonia, calcium hydroxide, lithium hydroxide, methylamine, potassium hydroxide, pyridine, rubidium hydroxide, sodium hydroxide, cesium hydroxide, strontium hydroxide, barium hydroxide, zinc hydroxide, tetraoctylammonium hydroxide, tetrahexylammonium hydroxide, tetrapentylammonium hydroxide, tetrabutylammonium hydroxide, tetrapropylammonium hydroxide, tetraethylammoniumhydroxide, and tetramethylammonium hydroxide.

In some embodiments, the percentage of hydroxy groups on the zinc oxide replaced by a silane compound is between about 10% and about 100%

In some embodiments, the percentage of hydroxy groups on the zinc oxide replaced by a silane is between about 60% and about 100%.

The present disclosure also provides an illumination device comprising:

(a) an electron transport layer, wherein the electron transport layer comprises at least one population of nanoparticles comprising a zinc oxide and at least one silane compound bound to the surface of the nanoparticles; and

(b) an emitting layer, wherein the emitting layer comprises at least one population of nanostructures.

In some embodiments, the nanoparticles comprising a zinc oxide in the illumination device are doped with at least one dopant.

In some embodiments, the nanoparticles comprising a zinc oxide in the illumination device are doped with at least one dopant selected from the group consisting of lithium, boron, carbon, nitrogen, fluorine, sodium, aluminum, silicon, chlorine, potassium, scandium, titanium, vanadium, chromium, manganese, nickel, gallium, arsenic, palladium, gold, cadmium, indium, tin, antimony, lead, and combinations thereof.

In some embodiments, the nanoparticles comprising a zinc oxide in the illumination device are alloyed with at least one metal ion.

In some embodiments, the nanoparticles comprising a zinc oxide in the illumination device are alloyed with magnesium ion.

In some embodiments, the at least one silane compound has the formula:

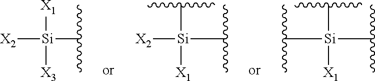

wherein:

X₁ is straight or branched C₁₋₂₀ alkyl;

X₂ is straight or branched C₁₋₂₀ alkyl or straight or branched C₁₋₂₀ alkoxy; and

X₃ is straight or branched C₁₋₂₀ alkyl or straight or branched C₁₋₂₀ alkoxy; wherein at least one of X₁, X₂, and X₃ is a straight or branched C₁₋₂₀ alkyl.

In some embodiments, X₁ is a straight C₁₋₂₀ alkyl and X₂ and X₃ are straight C₁₋₂₀ alkoxy.

In some embodiments, X₁ and X₂ are straight C₁₋₂₀ alkyl and X₃ is a straight C₁₋₂₀ alkoxy.

In some embodiments, the at least one silane compound is selected from the group consisting of dimethoxymethylsilyl-, diethoxymethylsilyl-, dipropoxymethylsilyl-, dibutoxymethylsilyl-, methoxydimethylsilyl-, ethoxydimethylsilyl-, dimethoxydodecylsilyl-, methoxydodecylmethylsilyl-, dimethoxyhexadecylsilyl-, dimethoxyoctadecylsilyl-, dimethoxy(n-octyl)silyl-, diethoxy(n-octyl)silyl-, ethoxyoctylmethylsilyl-, dimethoxypropylsilyl-, diethoxypropylsilyl-, dimethoxy(n-butyl)silyl-, diethoxy(n-butyl)silyl-, dimethoxy(i-butyl)silyl-, and diethoxy(i-butyl)silyl-.

In some embodiments, the at least one silane compound is dimethoxymethylsilyl-.

In some embodiments, the nanostructures in the emitting layer are quantum dots.

In some embodiments, the device is stable for at least 24 hours when stored at room temperature.

In some embodiments, the device is stable for between about 2 days and 7 days when stored at room temperature.

In some embodiments, the emitting layer of the illumination device comprises between one and five populations of nanostructures.

In some embodiments, the emitting layer of the illumination device comprises two populations of nanostructures.

In some embodiments, the emitting layer of the illumination device comprises at least one population of nanostructures comprising a core selected from the group consisting of InP, InZnP, InGaP, CdSe, CdS, CdSSe, CdZnSe, CdZnS, ZnSe, ZnTe, ZnSeTe, ZnS, ZnSSe, InAs, InGaAs, and InAsP.

In some embodiments, the emitting layer of the illumination device comprises at least one population of nanostructures comprising a core comprising InP.

In some embodiments, the illumination device is a light emitting diode.

The present disclosure also provides an illumination device comprising:

(a) a first conductive layer;

(b) a second conductive layer; and

(c) an electron transport layer, wherein the electron transport layer comprises at least one population of nanoparticles comprising a zinc oxide and at least one silane compound bound to the surface of the nanoparticles.

In some embodiments, the nanoparticles comprising a zinc oxide in the illumination device are doped with at least one dopant.

In some embodiments, the nanoparticles comprising a zinc oxide in the illumination device are doped with at least one dopant selected from the group consisting of lithium, boron, carbon, nitrogen, fluorine, sodium, aluminum, silicon, chlorine, potassium, scandium, titanium, vanadium, chromium, manganese, nickel, gallium, arsenic, palladium, gold, cadmium, indium, tin, antimony, lead, and combinations thereof.

In some embodiments, the nanoparticles comprising a zinc oxide in the illumination device are alloyed with at least one metal ion.

In some embodiments, the nanoparticles comprising a zinc oxide in the illumination device are alloyed with magnesium ion.

In some embodiments, the at least one silane compound has the formula:

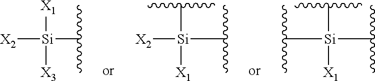

wherein:

X₁ is straight or branched C₁₋₂₀ alkyl;

X₂ is straight or branched C₁₋₂₀ alkyl or straight or branched C₁₋₂₀ alkoxy; and

X₃ is straight or branched C₁₋₂₀ alkyl or straight or branched C₁₋₂₀ alkoxy; wherein at least one of X₁, X₂, and X₃ is a straight or branched C₁₋₂₀ alkyl.

In some embodiments, X₁ is a straight C₁₋₂₀ alkyl and X₂ and X₃ are straight C₁₋₂₀ alkoxy.

In some embodiments, X₁ and X₂ are straight C₁₋₂₀ alkyl and X₃ is a straight C₁₋₂₀ alkoxy.

In some embodiments, the at least one silane compound is selected from the group consisting of dimethoxymethylsilyl-, diethoxymethylsilyl-, dipropoxymethylsilyl-, dibutoxymethylsilyl-, methoxydimethylsilyl-, ethoxydimethylsilyl-, dimethoxydodecylsilyl-, methoxydodecylmethylsilyl-, dimethoxyhexadecylsilyl-, dimethoxyoctadecylsilyl-, dimethoxy(n-octyl)silyl-, diethoxy(n-octyl)silyl-, ethoxyoctylmethylsilyl-, dimethoxypropylsilyl-, diethoxypropylsilyl-, dimethoxy(n-butyl)silyl-, diethoxy(n-butyl)silyl-, dimethoxy(i-butyl)silyl-, and diethoxy(i-butyl)silyl-.

In some embodiments, the at least one silane compound is dimethoxymethylsilyl-.

In some embodiments, the device is stable for at least 7 days when stored at room temperature.

In some embodiments, the device is stable for at least 14 days when stored at room temperature.

In some embodiments, the illumination device further comprises:

(d) an emitting layer.

In some embodiments, the emitting layer of the illumination device comprises between one and five populations of nanostructures.

In some embodiments, the emitting layer of the illumination device comprises two populations of nanostructures.

In some embodiments, the emitting layer of the illumination device comprises at least one population of nanostructures comprising a core selected from the group consisting of InP, InZnP, InGaP, CdSe, CdS, CdSSe, CdZnSe, CdZnS, ZnSe, ZnTe, ZnSeTe, ZnS, ZnSSe, InAs, InGaAs, and InAsP.

In some embodiments, the emitting layer of the illumination device comprises at least one population of nanostructures comprising a core comprising InP.

In some embodiments, the illumination device is a light emitting diode.

In some embodiments, the first conductive layer of the illumination device comprises indium tin oxide, indium zinc oxide, tin dioxide, zinc oxide, magnesium, aluminum, aluminum-lithium, calcium, magnesium-indium, magnesium-silver, silver, gold, or mixtures thereof.

In some embodiments, the first conductive layer of the illumination device comprises indium tin oxide.

In some embodiments, the second conductive layer of the illumination device comprises indium tin oxide, indium zinc oxide, titanium dioxide, tin oxide, zinc sulfide, silver, or mixtures thereof.

In some embodiments, the second conductive layer of the illumination device comprises aluminum.

In some embodiments, the second conductive layer of the illumination device comprises gold.

In some embodiments, the illumination device further comprises a semiconductor polymer layer.

In some embodiments, the semiconductor polymer layer of the illumination device comprises copper phthalocyanine, 4,4′,4″-tris[(3-methylphenyl)phenylamino] triphenylamine (m-MTDATA), 4,4′,4″-tris(diphenylamino) triphenylamine (TDATA), 4,4′,4″-tris[2-naphthyl(phenyl)amino] triphenylamine (2T-NATA), polyaniline/dodecylbenzenesulfonic acid, poly(3,4-ethylenedioxythiophene)/polystyrene sulfonate) (PEDOT/PSS), polyaniline/camphor sulfonic acid, or polyaniline/poly(4-styrenesulfonate).

In some embodiments, the semiconductor polymer layer of the illumination device comprises PEDOT/PSS.

In some embodiments, the illumination device further comprises a first transport layer.

In some embodiments, the first transport layer of the illumination device comprises N,N′-di(naphthalen-1-yl)-N,N′-bis(4-vinylphenyl)-4,4′-diamine, poly[(9,9-dioctylfluorenyl-2,7-diyl)-co-(4,4′-(N-(4-sec-butylphenyl))diphenylamine)], or poly(9-vinylcarbazole).

In some embodiments, the first transport layer of the illumination device comprises N,N′-di(naphthalen-1-yl)-N,N′-bis(4-vinylphenyl)-4,4′-diamine.

### BRIEF DESCRIPTION OF THE DRAWINGS

FIG. 1 are line graphs showing the absorption spectra of ZnMgO nanoparticles over time when stored at room temperature.

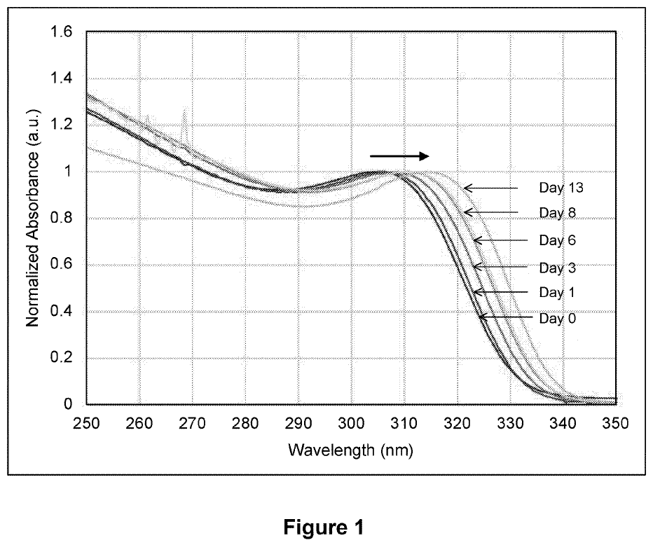

FIG. 2 is a line graph showing the change in the absorption wavelength of ZnMgO nanoparticles over time when stored at room temperature.

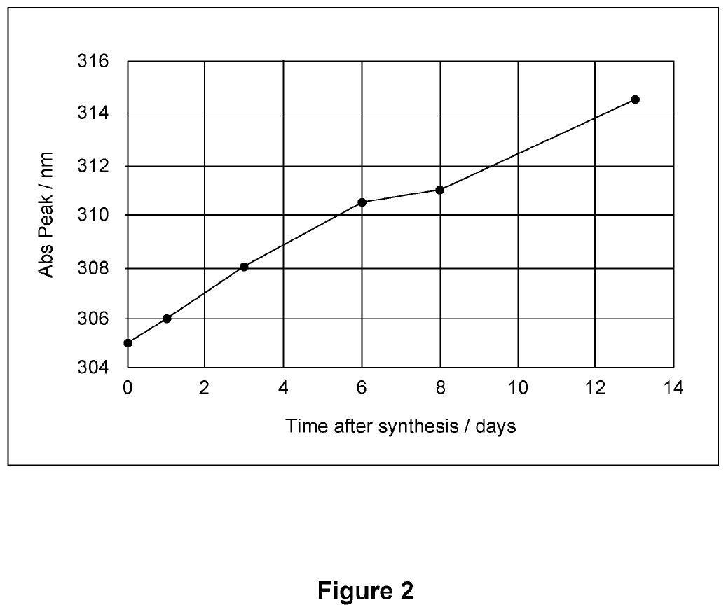

FIG. 3 is a line graph showing the change in the maximum external quantum efficiency (EQE) over time for blue-emitting quantum dot light emitting devices (QD-LEDs) prepared with ZnMgO stored at room temperature. FIG. 3 shows a decrease in the maximum EQE of devices prepared with ZnMgO over time.

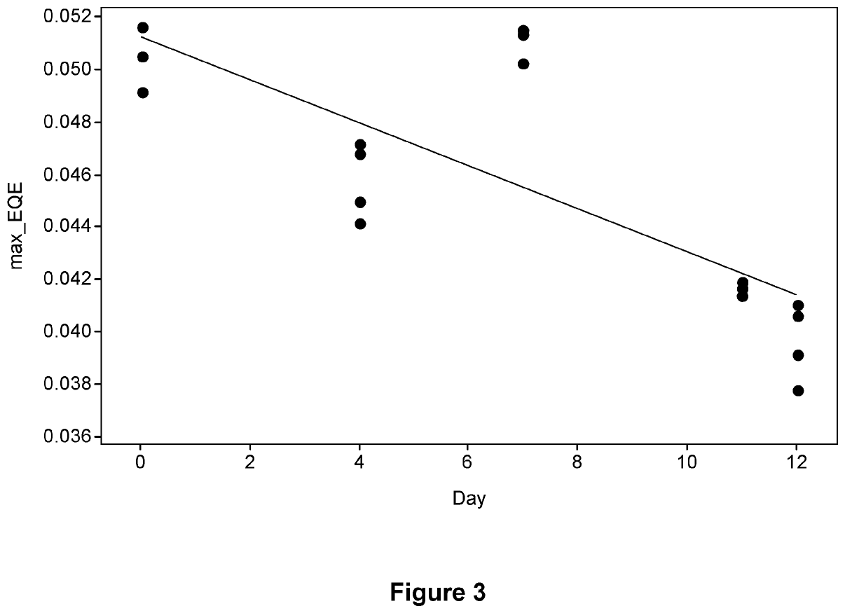

FIG. 4 is a schematic showing treatment of the surface of ZnO nanoparticles with an excess (5 equivalents to the number of Zn surface atoms) of trimethoxymethylsilane.

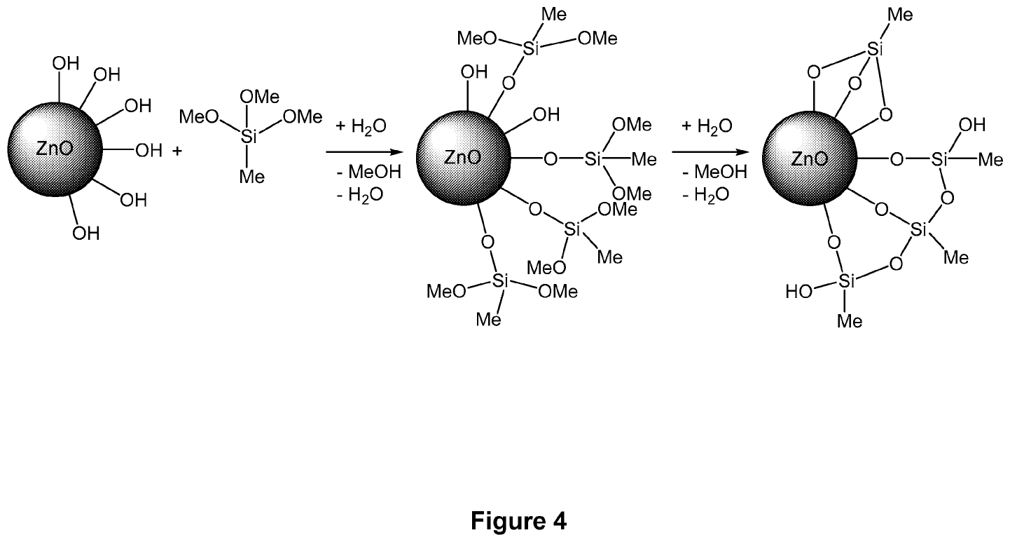

FIG. 5 are infrared spectra of ZnO nanoparticles with and without treatment with trimethoxymethylsilane.

FIG. 6 are line graphs showing the absorption spectra of (A) ZnO starting material; (B) untreated ZnO nanoparticles at day 0; (C) untreated ZnO nanoparticles at day 1; and (D) untreated ZnO nanoparticles at day 10.

FIG. 7 are line graphs showing the absorption spectra of (A) ZnO starting material; (B) trimethoxymethylsilane-treated ZnO nanoparticles at day 0; (C) trimethoxymethylsilane-treated ZnO nanoparticles at day 1; and (D) trimethoxymethylsilane-treated ZnO nanoparticles at day 8.

FIG. 8 is a graph showing maximum EQE for red-emitting QD-LEDs prepared with ethanolamine-treated ZnMgO nanoparticles in the electron transport layer, untreated ZnMgO nanoparticles in the electron transport layer, and trimethoxymethylsilane-treated ZnO nanoparticles after 2 and 7 days of storage at room temperature.

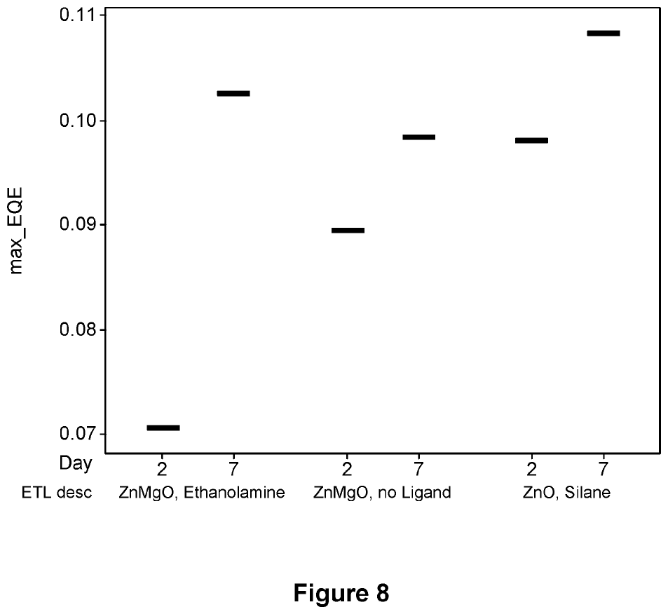

### DETAILED DESCRIPTION OF THE INVENTION

### Definitions

Unless defined otherwise, all technical and scientific terms used herein have the same meaning as commonly understood by one of ordinary skill in the art to which the invention pertains. The following definitions supplement those in the art and are directed to the current application and are not to be imputed to any related or unrelated case, e.g., to any commonly owned patent or application. Although any methods and materials similar or equivalent to those described herein can be used in the practice for testing of the present invention, the preferred materials and methods are described herein. Accordingly, the terminology used herein is for the purpose of describing particular embodiments only, and is not intended to be limiting.

As used in this specification and the appended claims, the singular forms “a,” “an,” and “the” include plural referents unless the context clearly dictates otherwise. Thus, for example, reference to “a nanostructure” includes a plurality of such nanostructures, and the like.

The term “about” as used herein indicates the value of a given quantity varies by +/−10% of the value, or +/−5% of the value, or +/−1% of the value so described. For example, “about 100 nm” encompasses a range of sizes from 90 nm to 110 nm, inclusive.

A “nanostructure” is a structure having at least one region or characteristic dimension with a dimension of less than about 500 nm. In some embodiments, the nanostructure has a dimension of less than about 200 nm, less than about 100 nm, less than about 50 nm, less than about 20 nm, or less than about 10 nm. Typically, the region or characteristic dimension will be along the smallest axis of the structure. Examples of such structures include nanowires, nanorods, nanotubes, branched nanostructures, nanotetrapods, tripods, bipods, nanocrystals, nanodots, quantum dots, nanoparticles, and the like. Nanostructures can be, e.g., substantially crystalline, substantially monocrystalline, polycrystalline, amorphous, or a combination thereof. In some embodiments, each of the three dimensions of the nanostructure has a dimension of less than about 500 nm, less than about 200 nm, less than about 100 nm, less than about 50 nm, less than about 20 nm, or less than about 10 nm.

The term “heterostructure” when used in reference to nanostructures refers to nanostructures characterized by at least two different and/or distinguishable material types. Typically, one region of the nanostructure comprises a first material type, while a second region of the nanostructure comprises a second material type. In certain embodiments, the nanostructure comprises a core of a first material and at least one shell of a second (or third etc.) material, where the different material types are distributed radially about the long axis of a nanowire, a long axis of an arm of a branched nanowire, or the center of a nanocrystal, for example. A shell can but need not completely cover the adjacent materials to be considered a shell or for the nanostructure to be considered a heterostructure; for example, a nanocrystal characterized by a core of one material covered with small islands of a second material is a heterostructure. In other embodiments, the different material types are distributed at different locations within the nanostructure; e.g., along the major (long) axis of a nanowire or along a long axis of arm of a branched nanowire. Different regions within a heterostructure can comprise entirely different materials, or the different regions can comprise a base material (e.g., silicon) having different dopants or different concentrations of the same dopant.

As used herein, the “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

The terms “crystalline” or “substantially crystalline,” when used with respect to nanostructures, refer to the fact that the nanostructures typically exhibit long-range ordering across one or more dimensions of the structure. It will be understood by one of skill in the art that the term “long range ordering” will depend on the absolute size of the specific nanostructures, as ordering for a single crystal cannot extend beyond the boundaries of the crystal. In this case, “long-range ordering” will mean substantial order across at least the majority of the dimension of the nanostructure. In some instances, a nanostructure can bear an oxide or other coating, or can be comprised of a core and at least one shell. In such instances it will be appreciated that the oxide, shell(s), or other coating can but need not exhibit such ordering (e.g. it can be amorphous, polycrystalline, or otherwise). In such instances, the phrase “crystalline,” “substantially crystalline,” “substantially monocrystalline,” or “monocrystalline” refers to the central core of the nanostructure (excluding the coating layers or shells). The terms “crystalline” or “substantially crystalline” as used herein are intended to also encompass structures comprising various defects, stacking faults, atomic substitutions, and the like, as long as the structure exhibits substantial long range ordering (e.g., order over at least about 80% of the length of at least one axis of the nanostructure or its core). In addition, it will be appreciated that the interface between a core and the outside of a nanostructure or between a core and an adjacent shell or between a shell and a second adjacent shell can contain non-crystalline regions and can even be amorphous. This does not prevent the nanostructure from being crystalline or substantially crystalline as defined herein.

The term “dopant” means those cations, or portions of cations, that are intimately incorporated into the crystalline lattice structure of the zinc oxide thereby modifying the electronic properties of the zinc oxide.

The term “monocrystalline” when used with respect to a nanostructure indicates that the nanostructure is substantially crystalline and comprises substantially a single crystal. When used with respect to a nanostructure heterostructure comprising a core and one or more shells, “monocrystalline” indicates that the core is substantially crystalline and comprises substantially a single crystal.

A “nanocrystal” is a nanostructure that is substantially monocrystalline. A nanocrystal thus has at least one region or characteristic dimension with a dimension of less than about 500 nm. In some embodiments, the nanocrystal has a dimension of less than about 200 nm, less than about 100 nm, less than about 50 nm, less than about 20 nm, or less than about 10 nm. The term “nanocrystal” is intended to encompass substantially monocrystalline nanostructures comprising various defects, stacking faults, atomic substitutions, and the like, as well as substantially monocrystalline nanostructures without such defects, faults, or substitutions. In the case of nanocrystal heterostructures comprising a core and one or more shells, the core of the nanocrystal is typically substantially monocrystalline, but the shell(s) need not be. In some embodiments, each of the three dimensions of the nanocrystal has a dimension of less than about 500 nm, less than about 200 nm, less than about 100 nm, less than about 50 nm, less than about 20 nm, or less than about 10 nm.

The term “quantum dot” (or “dot”) refers to a nanocrystal that exhibits quantum confinement or exciton confinement. Quantum dots can be substantially homogenous in material properties, or in certain embodiments, can be heterogeneous, e.g., including a core and at least one shell. The optical properties of quantum dots can be influenced by their particle size, chemical composition, and/or surface composition, and can be determined by suitable optical testing available in the art. The ability to tailor the nanocrystal size, e.g., in the range between about 1 nm and about 15 nm, enables photoemission coverage in the entire optical spectrum to offer great versatility in color rendering.

A “ligand” is a molecule capable of interacting (whether weakly or strongly) with one or more faces of a nanostructure, e.g., through covalent, ionic, van der Waals, or other molecular interactions with the surface of the nanostructure.

“Photoluminescence quantum yield” is the ratio of photons emitted to photons absorbed, e.g., by a nanostructure or population of nanostructures. As known in the art, quantum yield is typically determined by a comparative method using well-characterized standard samples with known quantum yield values.

“Peak emission wavelength” (PWL) is the wavelength where the radiometric emission spectrum of the light source reaches its maximum.

As used herein, the term “shell” refers to material deposited onto the core or onto previously deposited shells of the same or different composition and that result from a single act of deposition of the shell material. The exact shell thickness depends on the material as well as the precursor input and conversion and can be reported in nanometers or monolayers. As used herein, “target shell thickness” refers to the intended shell thickness used for calculation of the required precursor amount. As used herein, “actual shell thickness” refers to the actually deposited amount of shell material after the synthesis and can be measured by methods known in the art. By way of example, actual shell thickness can be measured by comparing particle diameters determined from transmission electron microscopy (TEM) images of nanocrystals before and after a shell synthesis.

As used herein, the term “monolayer” is a measurement unit of shell thickness derived from the bulk crystal structure of the shell material as the closest distance between relevant lattice planes. By way of example, for cubic lattice structures the thickness of one monolayer is determined as the distance between adjacent lattice planes in the [111] direction. By way of example, one monolayer of cubic ZnSe corresponds to 0.328 nm and one monolayer of cubic ZnS corresponds to 0.31 nm thickness. The thickness of a monolayer of alloyed materials can be determined from the alloy composition through Vegard's law.

As used herein, the term “full width at half-maximum” (FWHM) is a measure of the size distribution of quantum dots. The emission spectra of quantum dots generally have the shape of a Gaussian curve. The width of the Gaussian curve is defined as the FWHM and gives an idea of the size distribution of the particles. A smaller FWHM corresponds to a narrower quantum dot nanocrystal size distribution. FWHM is also dependent upon the emission wavelength maximum.

As used herein, the term “external quantum efficiency” (EQE) is a ratio of the number of photons emitted from a light emitting diode (LED) to the number of electrons passing through the device. The EQE measures how efficiently a LED converts electrons to photons and allows them to escape. EQE can be measured using the formula:

EQE=[injection efficiency]×[solid-state quantum yield]×[extraction efficiency]

where:

injection efficiency=the proportion of electrons passing through the device that are injected into the active region;

solid-state quantum yield=the proportion of all electron-hole recombinations in the active region that are radiative and thus, produce photons; and

extraction efficiency=the proportion of photons generated in the active region that escape from the device.

As used herein, the term “stable” refers to a mixture or composition that resists change or decomposition due to internal reaction or due to the action of air, heat, light, pressure, or other natural conditions. The stability of a nanostructure composition can be determined by measuring the peak absorption wavelength after admixing at least one population of nanostructure comprising nanoparticles comprising zinc oxide with at least one silane compound. The peak emission wavelength can be measured by irradiating a nanostructure composition with UV or blue (450 nm) light and measuring the output with a spectrometer. The absorption spectrum is compared to the absorption from the original nanostructure composition. A nanostructure composition is stable if the peak absorption wavelength does not shift by more than 5 nm.

“Alkyl” as used herein refers to a straight or branched, saturated, aliphatic radical having the number of carbon atoms indicated. In some embodiments, the alkyl is C₁₋₂ alkyl, C₁₋₃ alkyl, C₁₋₄ alkyl, C₁₋₅ alkyl, C₁₋₆ alkyl, C₁₋₇ alkyl, C₁₋₈ alkyl, C₁₋₉ alkyl, C₁₋₁₀ alkyl, C₁₋₁₂ alkyl, C₁₋₁₄ alkyl, C₁₋₁₆ alkyl, C₁₋₁₈ alkyl, C₁₋₂₀ alkyl, C₈₋₂₀ alkyl, C₁₂₋₂₀ alkyl, C₁₄₋₂₀ alkyl, C₁₆₋₂₀ alkyl, or C₁₈₋₂₀ alkyl. For example, C₁₋₆ alkyl includes, but is not limited to, methyl, ethyl, propyl, isopropyl, butyl, isobutyl, sec-butyl, tert-butyl, pentyl, isopentyl, and hexyl. In some embodiments, the alkyl is octyl, nonyl, decyl, undecyl, dodecyl, tridecyl, tetradecyl, pentadecyl, hexadecyl, heptadecyl, octadecyl, nonadecyl, or icosanyl.

“Alkoxy” as used herein refers to the group —O-alkoxy. In some embodiments, the alkoxyl is —O—C₁₋₂ alkoxy, —O—C₁₋₃ alkoxy, —O—C₁₋₄ alkoxy, alkoxy, —O—C₁₋₆ alkoxy, —O—C₁₋₇ alkoxy, alkoxy, —O—C₁₋₉ alkoxy, alkoxy, —O—C₁₋₁₂ alkoxy, —O—C₁₋₁₄ alkoxy, —O—C₁₋₁₆ alkoxy, —O—C₁₋₁₈ alkoxy, —O—C₁₋₂₀ alkoxy, —O—C₈₋₂₀ alkoxy, —O—C₁₂₋₂₀ alkoxy, —O—C₁₄₋₂₀ alkoxy, —O—C₁₆₋₂₀ alkoxy, or —O—C₁₈₋₂₀ alkoxy. For example, —O—C₁₋₆ alkoxy includes, but is not limited to, methoxy, ethoxy, propoxy, isopropoxy, butoxy, isobutoxy, sec-butoxy, tert-butoxy, pentoxy, isopentoxy, and hexoxy. In some embodiments, the alkoxy is octoxy, nonoxy, decoxy, undecoxy, dodecoxy, tridecoxy, tetradecoxy, pentadecoxy, hexadecoxy, heptadecoxy, octadecoxy, nonadecoxy, or icosanyloxy.

Unless clearly indicated otherwise, ranges listed herein are inclusive.

A variety of additional terms are defined or otherwise characterized herein.

### Illumination Devices

In some embodiments, the nanoparticles comprising zinc oxide can be used in the electron transport layer of an illumination device.

The illumination device can be used in a wide variety of applications, such as flexible electronics, touchscreens, monitors, televisions, cellphones, and any other high definition displays. In some embodiments, the illumination device is a light emitting diode. In some embodiments, the illumination device is a quantum dot light emitting diode (QD-LED). An example of a QD-LED is disclosed in U.S. patent application Ser. No. 15/824,701, which is incorporated herein by reference in its entirety.

In some embodiments, the present disclosure provides an illumination device comprising:

(a) an electron transport layer, wherein the electron transport layer comprises at least one population of nanoparticles comprising zinc oxide and at least one silane compound bound to the surface of the nanoparticles; and

(b) an emitting layer, wherein the emitting layer comprises at least one population of nanostructures.

In some embodiments, the present disclosure provides an illumination device comprising:

(a) a first conductive layer;

(b) a second conductive layer; and

(c) an electron transport layer, wherein the electron transport layer comprises at least one population of nanoparticles comprising zinc oxide and at least one silane compound bound to the surface of the nanoparticles.

In some embodiments, the illumination device comprises:

(a) a first conductive layer;

(b) a second conductive layer;

(c) an electron transport layer, wherein the electron transport layer comprises at least one population of nanoparticles comprising zinc oxide and at least one silane compound bound to the surface of the nanoparticles; and

(d) an emitting layer, wherein the emitting layer comprises at least one population of nanostructures.

In some embodiments, the nanostructures are quantum dots.

In some embodiments, the illumination device comprises a first conductive layer, a second conductive layer, and an electron transport layer, wherein the electron transport layer is arranged between the first conductive layer and the second conductive layer. In some embodiments, the electron transport layer is a thin film.

In some embodiments, the illumination device comprises additional layers between the first conductive layer and the second conductive layer such as a hole injection layer, a hole transport layer, an electron transport layer, and an emitting layer. In some embodiments, the hole injection layer, the hole transport layer, the electron transport layer, and the emitting layer are thin films. In some embodiments, the layers are stacked on a substrate.

When voltage is applied to the first conductive layer and the second conductive layer, holes injected at the first conductive layer move to the emitting layer via the hole injection layer and/or the hole transport layer, and electrons injected from the second conductive layer move to the emitting layer via the electron transport layer. The holes and electrons recombine in the emitting layer to generate excitons.

### Substrate

The substrate can be any substrate that is commonly used in the manufacture of illumination devices. In some embodiments, the substrate is a transparent substrate, such as glass. In some embodiments, the substrate is a flexible material such as polyimide, or a flexible and transparent material such as polyethylene terephthalate. In some embodiments, the substrate has a thickness of between about 0.1 mm and about 2 mm. In some embodiments, the substrate is a glass substrate, a plastic substrate, a metal substrate, or a silicon substrate.

### First Conductive Layer

In some embodiments, a first conductive layer is disposed on the substrate. In some embodiments, the first conductive layer is a stack of conductive layers. In some embodiments, the first conductive layer has a thickness between about 50 nm and about 250 nm. In some embodiments, the first conductive layer is deposited as a thin film using any known deposition technique, such as, for example, sputtering or electron-beam evaporation. In some embodiments, the first conductive layer comprises indium tin oxide (ITO), indium zinc oxide (IZO), tin dioxide (SnO₂), zinc oxide (ZnO), magnesium (Mg), aluminum (Al), aluminum-lithium (Al—Li), calcium (Ca), magnesium-indium (Mg—In), magnesium-silver (Mg—Ag), silver (Ag), gold (Au), or mixtures thereof. In some embodiments, the first conductive layer is an anode.

### Second Conductive Layer

In some embodiments, additional layers can be sandwiched between a first conductive layer and a second conductive layer. In some embodiments, the first conductive layer acts as the anode of the device while the second conductive layer acts as the cathode of the device. In some embodiments, the second conductive layer is a metal, such as aluminum. In some embodiments, the second conductive layer has a thickness between about 100 nm and about 150 nm. In some embodiments, the second conductive layer represents a stack of conductive layers. For example, a second conductive layer can include a layer of silver sandwiched between two layers of ITO (ITO/Ag/ITO).

In some embodiments, the second conductive layer comprises indium tin oxide (ITO), an alloy of indium oxide and zinc (IZO), titanium dioxide, tin oxide, zinc sulfide, silver (Ag), or mixtures thereof.

### Semiconductor Polymer Layer

In some embodiments, the illumination device further comprises a semiconductor polymer layer. In some embodiments, the semiconductor polymer layer acts as a hole injection layer. In some embodiments, the semiconductor polymer layer is deposited on the first conductive layer. In some embodiments, the semiconductor polymer layer is deposited by vacuum deposition, spin-coating, printing, casting, slot-die coating, or Langmuir-Blodgett (LB) deposition. In some embodiments, the semiconductor polymer layer has a thickness between about 20 nm and about 60 nm.

In some embodiments, the semiconductor polymer layer comprises copper phthalocyanine, 4,4′,4″-tris[(3-methylphenyl)phenylamino] triphenylamine (m-MTDATA), 4,4′,4″-tris(diphenylamino) triphenylamine (TDATA), 4,4′,4″-tris[2-naphthyl(phenyl)amino] triphenylamine (2T-NATA), polyaniline/dodecylbenzenesulfonic acid, poly(3,4-ethylenedioxythiophene)/polystyrene sulfonate) (PEDOT/PSS), polyaniline/camphor sulfonic acid, or polyaniline/poly(4-styrenesulfonate).

### First Transport Layer

In some embodiments, the illumination device further comprises transport layers to facilitate the transport of electrons and holes affected by the generated electric field between the first conductive layer and the second conductive layer. In some embodiments, the illumination device further comprises a first transport layer associated with the first conductive layer. In some embodiments, the first transport layer acts as a hole transport layer (and an electron and/or exciton blocking layer). In some embodiments, the first transport layer is deposited on the first conductive layer. In some embodiments, the first transport layer is deposited on the semiconductor polymer layer.

In some embodiments, the first transport layer has a thickness between about 20 nm and about 50 nm. In some embodiments, the first transport layer is substantially transparent to visible light.

In some embodiments, the first transport layer comprises a material selected from the group consisting of an amine, a triarylamine, a thiophene, a carbazole, a phthalocyanine, a porphyrin, or a mixture thereof. In some embodiments, the first transport layer comprises N,N′-di(naphthalen-1-yl)-N,N′-bis(4-vinylphenyl)-4,4′-diamine, poly[(9,9-dioctylfluorenyl-2,7-diyl)-co-(4,4′-(N-(4-sec-butylphenyl))diphenylamine)], and poly(9-vinylcarbazole).

### Second Transport Layer

In some embodiments, the illumination device further comprises a second transport layer. In some embodiments, the second transport layer acts as an electron transport layer (and a hole and/or exciton blocking layer). In some embodiments, the second transport layer contacts the emitting layer. In some embodiments, the second transport layer is arranged between the emitting layer and the second conductive layer. In some embodiments, the second transport layer has a thickness between about 20 nm and about 50 nm. In some embodiments, the second transport layer is substantially transparent to visible light.

In some embodiments, the second transport layer is an electron transport layer.

The roles of the first transport layer and the second transport layer are reversed when the polarity of the first conductive layer and the second conductive layer are reversed.

### Electron Transport Layer

In some embodiments, the illumination device comprises at least one electron transport layer. In some embodiments, the illumination device is a quantum dot light emitting diode.

In some embodiments, the electron transport layer has a thickness between about 20 nm and about 50 nm. In some embodiments, the electron transport layer has a thickness between about 20 nm and about 50 nm, about 20 nm and about 40 nm, about 20 nm and about 30 nm, about 30 nm and about 50 nm, about 30 nm and about 40 nm, or about 40 nm and about 50 nm.

In some embodiments, the electron transport layer comprises a zinc oxide nanoparticle composition. In some embodiments, the electron transport layer comprises a nanoparticle composition comprising:

(a) at least one population of zinc oxide nanoparticles; and

(b) at least one silane compound bound to the surface of the nanoparticles.

### Zinc Oxide Nanoparticle Composition

In some embodiments, the present disclosure provides a nanoparticle composition comprising:

(a) at least one population of zinc oxide nanoparticles; and

(b) at least one silane compound bound to the surface of the nanoparticles.

In some embodiments, the nanoparticles comprising zinc oxide are doped or alloyed with at least one metal ion.

### Zinc Oxide Nanoparticle

In some embodiments, the zinc oxide nanoparticle has an average particle size between about 3 nm and about 50 nm. In some embodiments, the zinc oxide nanoparticle has an average particle size between about 3 nm and about 50 nm, about 3 nm and about 40 nm, about 3 nm and about 30 nm, about 3 nm and about 20 nm, about 3 nm and about 10 nm, about 10 nm and about 50 nm, about 10 nm and about 40 nm, about 10 nm and about 30 nm, about 10 nm and about 20 nm, about 20 nm and about 50 nm, about 20 nm and about 40 nm, about 20 nm and about 30 nm, about 30 nm and about 50 nm, about 30 nm and about 40 nm, or about 40 nm and about 50 nm.

In some embodiments, the zinc oxide nanostructure is doped with at least one dopant. In some embodiments, the dopant is a metal ion. Doping is the intentional introduction of an impurity into a nanostructure for the purpose of altering its optical, electrical, chemical, and/or magnetic properties. Yim, K., et al., Scientific Reports 7:40907 (January 2017). In doping, very small quantities of a metal ion are used resulting in only minor distortions of the lattice of the nanostructure. In some embodiments, the concentration of dopant is between about 10¹⁵/cm³ and about 10²⁰/cm³.

In some embodiments, the zinc oxide nanoparticle is doped with at least one dopant selected from the group consisting of lithium, boron, carbon, nitrogen, fluorine, sodium, aluminum, silicon, chlorine, potassium, scandium, titanium, vanadium, chromium, manganese, nickel, gallium, arsenic, palladium, gold, cadmium, indium, tin, antimony, lead, and combinations thereof. In some embodiments, the zinc oxide nanoparticle is doped with at least one dopant selected from the group consisting of indium, gallium, aluminum, titanium, tin, chlorine, fluorine, and combinations thereof.

In some embodiments, the zinc oxide nanoparticle is alloyed with at least one metal ion. An alloy is a combination of at least two metals or a combination of at least one metal ion and at least one other element. In forming an alloy, large concentrations of a metal ion are used resulting in properties that are often different from the pure metal or metal oxide they contain. In some embodiments, the concentration of metal ion alloyed with zinc oxide is between about 0.1 wt % and about 50 wt %.

In some embodiments, the zinc oxide nanoparticle is alloyed with at least one metal or element selected from the group consisting of copper and magnesium. In some embodiments, the zinc oxide nanoparticle is alloyed with magnesium.

### Silane Ligand

In some embodiments, the nanoparticle composition comprises at least one silane compound bound to the surface of the nanoparticles. In some embodiments, the at least one silane compound is covalently bound to the surface of the nanoparticles.

In some embodiments, the at least one silane compound has the formula:

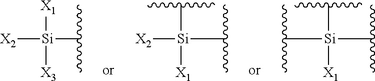

wherein:

X₁ is straight or branched C₁₋₂₀ alkyl;

X₂ is straight or branched C₁₋₂₀ alkyl or straight or branched C₁₋₂₀ alkoxy; and

X₃ is straight or branched C₁₋₂₀ alkyl or straight or branched C₁₋₂₀ alkoxy; wherein at least one of X₁, X₂, and X₃ is a straight or branched C₁₋₂₀ alkyl.

In some embodiments, X₁ is a straight C₁₋₂₀ alkyl and X₂ and X₃ are straight C₁₋₂₀ alkoxy. In some embodiments, X₁ and X₂ are straight C₁₋₂₀ alkyl and X₃ is a straight C₁₋₂₀ alkoxy. In some embodiments, X₁, X₂, and X₃ are straight C₁₋₂₀ alkyl. In some embodiments, X₁, X₂, and X₃ are straight C₁₋₂₀ alkoxy.

In some embodiments, the silane compound is dimethoxymethylsilyl-, diethoxymethylsilyl-, dipropoxymethylsilyl-, dibutoxymethylsilyl-, methoxydimethylsilyl-, ethoxydimethylsilyl-, dimethoxydodecylsilyl-, methoxydodecylmethylsilyl-, dimethoxyhexadecylsilyl-, dimethoxyoctadecylsilyl-, dimethoxy(n-octyl)silyl-, diethoxy(n-octyl)silyl-, ethoxyoctylmethylsilyl-, dimethoxypropylsilyl-, diethoxypropylsilyl-, dimethoxy(n-butyl)silyl-, diethoxy(n-butyl)silyl-, dimethoxy(i-butyl)silyl-, and diethoxy(i-butyl)silyl-. In some embodiments, the silane compound is dimethoxymethylsilyl-.

Method of Making Nanoparticles Comprising Zinc Oxide Functionalized with Silane Compounds

During the synthesis of nanoparticles comprising zinc oxide functionalized with silane compounds, an excess of silane is added when the nanoparticles comprising zinc oxide have reached the desired size or optical band gap. The alkoxy groups of the silane are hydrolyzed by base or water in the reaction mixture and the resulting silanol condenses with surface hydroxy groups of the nanoparticles comprising zinc oxide forming Zn—O—Si bonds (SCHEME 1). In further reactions, if there are additional alkoxy groups on the silicon atom, these can condense with additional Zn—OH surface groups or with Si—OH groups of neighboring silanes (SCHEME 2). The alkyl substituents on the silicon do not hydrolyze and therefore terminate the surface. This treatment results in a coating of silane compounds covalently bound to the zinc oxide surface without a pathway for further ZnO growth or aggregation.

In some embodiments, the functionalized nanoparticles comprising zinc oxide are prepared from silanes by the reaction shown in SCHEME 1.

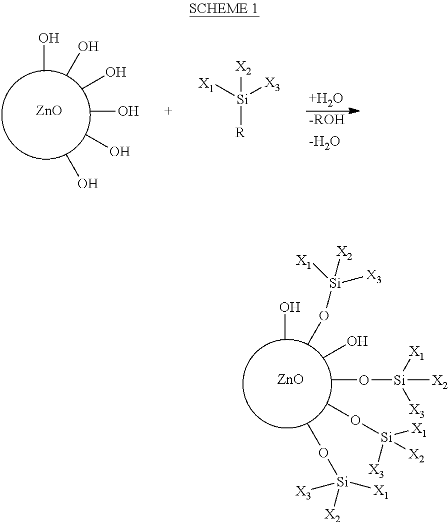

wherein:

R is a straight or branched C₁₋₂₀ alkoxy;

X₁ is a straight or branched C₁₋₂₀ alkyl or straight or branched C₁₋₂₀ alkoxy;

X₂ is a straight or branched C₁₋₂₀ alkyl or straight or branched C₁₋₂₀ alkoxy; and

X₃ is a straight or branched C₁₋₂₀ alkyl or straight or branched C₁₋₂₀ alkoxy, wherein at least one of X₁, X₂, and X₃ is a straight or branched C₁₋₂₀ alkyl.

In some embodiments, where two of X₁, X₂, and X₃ are a straight or branched C₁₋₂₀ alkoxy and one of X₁, X₂, and X₃ is a straight or branched C₁₋₂₀ alkyl, the functionalized nanoparticles comprising zinc oxide are prepared from silanes by the reaction shown in SCHEME 2.

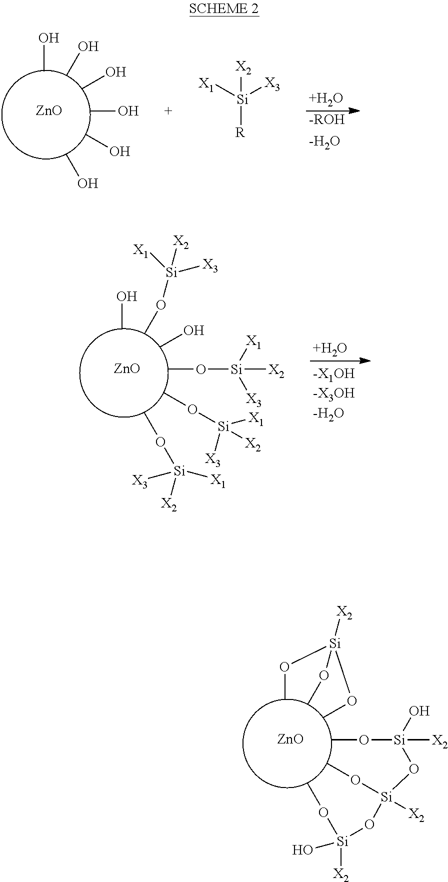

wherein:

R is a straight or branched C₁₋₂₀ alkoxy;

X₁ is a straight or branched C₁₋₂₀ alkoxy;

X₂ is a straight or branched C₁₋₂₀ alkyl; and

X₃ is a straight or branched C₁₋₂₀ alkoxy.

In some embodiments, the present disclosure is directed to a method of preparing a nanoparticle composition comprising:

(a) admixing a reaction mixture comprising a population of nanoparticles comprising zinc oxide having at least one hydroxy group covalently bound to the nanoparticle with at least one silane; and

(b) adding a reactant comprising water, at least one base, or a combination thereof to the reaction mixture in (a).

In some embodiments, the silane is an alkoxyalkylsilane.

In some embodiments, the at least one silane has the formula:

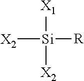

wherein:

R is a straight or branched C₁₋₂₀ alkoxy;

X₁ is a straight or branched C₁₋₂₀ alkyl or straight or branched C₁₋₂₀ alkoxy;

X₂ is a straight or branched C₁₋₂₀ alkyl or straight or branched C₁₋₂₀ alkoxy; and

X₃ is a straight or branched C₁₋₂₀ alkyl or straight or branched C₁₋₂₀ alkoxy; wherein at least one of X₁, X₂, and X₃ is a straight or branched C₁₋₂₀ alkyl.

In some embodiments, the silane is an alkoxyalkylsilane.

In some embodiments, X₁ is a straight C₁₋₂₀ alkyl and X₂ and X₃ are straight C₁₋₂₀ alkoxy. In some embodiments, X₁ and X₂ are straight C₁₋₂₀ alkyl and X₃ is a straight C₁₋₂₀ alkoxy. In some embodiments, X₁, X₂, and X₃ are straight C₁₋₂₀ alkyl. In some embodiments, X₁, X₂, and X₃ are straight C₁₋₂₀ alkoxy.

In some embodiments, the alkoxyalkylsilane is trimethoxymethylsilane, triethoxymethylsilane, tripropoxymethylsilane, tributoxymethylsilane, dimethoxydimethylsilane, diethoxydimethylsilane, trimethoxydodecylsilane, dimethoxydodecylmethylsilane, trimethoxyhexadecylsilane, trimethoxyoctadecylsilane, trimethoxy(n-octyl)silane, triethoxy(n-octyl)silane, diethoxyoctylmethylsilane, trimethoxypropylsilane, triethoxypropylsilane, trimethoxy(n-butyl)silane, triethoxy(n-butyl)silane, trimethoxy(i-butyl)silane, or triethoxy(i-butyl)silane. In some embodiments, the alkoxyalkylsilane is trimethoxymethylsilane.

In some embodiments, the admixing in (a) is performed at a temperature between about 0° C. and about 200° C., about 0° C. and about 150° C., about 0° C. and about 100° C., about 0° C. and about 80° C., about 20° C. and about 200° C., about 20° C. and about 150° C., about 20° C. and about 100° C., about 20° C. and about 80° C., about 50° C. and about 200° C., about 50° C. and about 150° C., about 50° C. and about 100° C., about 50° C. and about 80° C., about 80° C. and about 200° C., about 80° C. and about 150° C., about 80° C. and about 100° C., about 100° C. and about 200° C., about 100° C. and about 150° C., or about 150° C. and about 200° C. In some embodiments, the admixing in (a) is performed at a temperature between about 10° C. and about 30° C. In some embodiments, the admixing in (a) is performed at a temperature of between about 20° C. and about 25° C.

In some embodiments, the admixing in (a) is performed over a period of about 1 minute and about 6 hours, about 1 minute and about 2 hours, about 1 minute and about 1 hour, about 1 minute and about 40 minutes, about 1 minute and about 30 minutes, about 1 minute and about 20 minutes, about 1 minute and about 10 minutes, about 10 minutes and about 6 hours, about 10 minutes and about 2 hours, about 10 minutes and about 1 hour, about 10 minutes and about 40 minutes, about 10 minutes and about 30 minutes, about 10 minutes and about 20 minutes, about 20 minutes and about 6 hours, about 20 minutes and about 2 hours, about 20 minutes and about 1 hour, about 20 minutes and about 40 minutes, about 20 minutes and about 30 minutes, about 30 minutes and about 6 hours, about 30 minutes and about 2 hours, about 30 minutes and about 1 hour, about 30 minutes and about 40 minutes, about 40 minutes and about 6 hours, about 40 minutes and about 2 hours, about 40 minutes and about 1 hour, about 1 hour and about 6 hours, about 1 hour and about 2 hours, or about 2 hours and about 6 hours. In some embodiments, the admixing is performed over a period of about 40 minutes and about 2 hours. In some embodiments, the admixing in (a) is performed over a period of about 1 hour. In some embodiments, the admixing in (a) is performed over a period of about 2 hours.

In some embodiments, the reaction mixture in (a) further comprises a solvent. In some embodiments, the solvent is selected from the group consisting of chloroform, acetone, butanone, dimethylsulfoxide, N,N-dimethylformamide, N-methylformamide, formamide, tetrahydrofuran, 2-methyltetrahydrofuran, ethylene glycol monoethyl ether, ethylene glycol monopropyl ether, 1,4-butanediol diacetate, diethylene glycol monobutyl ether acetate, ethylene glycol monobutyl ether acetate, glyceryl triacetate, heptyl acetate, hexyl acetate, pentyl acetate, butyl acetate, ethyl acetate, diethylene glycol butyl methyl ether, diethylene glycol monobutyl ether, di(propylene glycol) dimethyl ether, diethylene glycol ethyl methyl ether, ethylene glycol monobutyl ether, diethylene glycol diethyl ether, methyl isobutyl ketone, monomethyl ether glycol ester, gamma-butyrolactone, methylacetic-3-ethyl ether, butyl carbitol, butyl carbitol acetate, propanediol monomethyl ether, propanediol monomethyl ether acetate, cyclohexane, toluene, xylene, 1-butanol, 2-butanol, isopropyl alcohol, ethanol, 2-methoxyethanol, methanol, and combinations thereof. In some embodiments, the solvent is ethanol.

The number of surface atoms of a single spherical nanocrystal can be calculated as

$${N}_{surface} = \frac{{V}_{s u r f a c e} \cdot ρ}{M} \cdot {N}_{A}$$

from the volume of the surface monolayer

$${V}_{surface} = \frac{π}{6} ( {d}^{3} - {( d - {d}_{M L} )}^{3} )$$

where d is the nanocrystal diameter, d_{ML} is the thickness of a monolayer of the nanocrystal (for ZnO d_{ML}=0.258 nm, half a unit cell along the c axis), ρ is the density of the nanocrystal material, M is the molecular weight of the nanocrystal material, and N_{A} is the Avogadro constant.

For a colloidal solution of a given mass concentration of nanocrystals the molar concentration of surface atoms can be calculated as

$${c}_{surface} = \frac{6 β \cdot {N}_{s u r f a c e}}{π {d}^{3} ρ \cdot {N}_{A}} .$$

In some embodiments, the ratio of silane or alkoxyalkylsilane to the number of Zn surface atoms is between about 2 equivalents and about 10 equivalents, about 2 equivalents and about 8 equivalents, about 2 equivalents and about 6 equivalents, about 2 equivalents and about 5 equivalents, about 2 equivalents and about 4 equivalents, about 2 equivalents and about 3 equivalents, about 3 equivalents and about 10 equivalents, about 3 equivalents and about 8 equivalents, about 3 equivalents and about 6 equivalents, about 3 equivalents and about 5 equivalents, about 3 equivalents and about 4 equivalents, about 4 equivalents to about 10 equivalents, about 4 equivalents and about 8 equivalents, about 4 equivalents and about 6 equivalents, about 4 equivalents and about 5 equivalents, about 5 equivalents to about 10 equivalents, about 5 equivalents and about 8 equivalents, about 5 equivalents and about 6 equivalents, about 6 equivalents to about 10 equivalents, about 6 equivalents and about 8 equivalents, or about 8 equivalents and about 10 equivalents. In some embodiments, the ratio of silane or alkoxyalkylsilane to the number of Zn surface atoms is about 5 equivalents.

In some embodiments, the reactant added in (b) comprises water. In some embodiments, water is the only reactant added in (b).

In some embodiments, the reactant added in (b) comprises a base. In some embodiments, a base is the only reactant added in (b). In some embodiments, the reactant added in (b) comprises a base selected from the group consisting of acetone, ammonia, calcium hydroxide, lithium hydroxide, methylamine, potassium hydroxide, pyridine, rubidium hydroxide, sodium hydroxide, cesium hydroxide, strontium hydroxide, barium hydroxide, zinc hydroxide, tetraoctylammonium hydroxide, tetrahexylammonium hydroxide, tetrapentylammonium hydroxide, tetrabutylammonium hydroxide, tetrapropylammonium hydroxide, tetraethylammoniumhydroxide, and tetramethylammonium hydroxide.

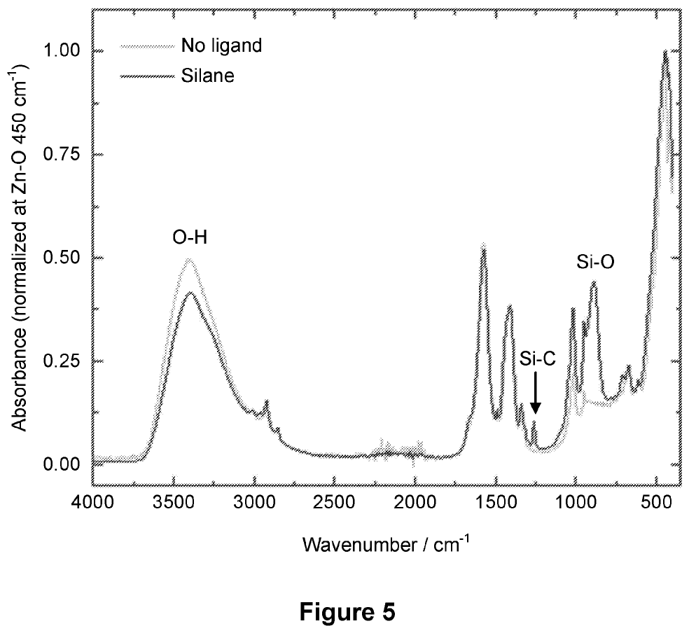

The percentage of hydroxy groups replaced by a silane or alkoxyalkylsilane compound can be measured by infrared spectroscopy. As shown in FIG. 5, the presence of a silane coating can be shown by infrared spectroscopy. In FIG. 5, the signals at 890 cm⁻¹ and 1260 cm⁻¹ are assigned to Si—O and Si—C vibrations, respectively. The intensity of the hydroxy band in the 3100-3600 cm⁻¹ range decreased as the extent of silane coating increased. However, as shown in FIG. 5, hydroxy groups are still present and can be located on Zn or Si atoms. This explains why the treated particles are still soluble in polar solvents such as ethanol.

In some embodiments, the percentage of hydroxy groups on the zinc oxide replaced by a silane compound is between about 10% and about 100%, about 10% and about 80%, about 10% and about 60%, about 10% and about 40%, about 10% and about 30%, about 10% and about 20%, about 20% and about 100%, about 20% and about 80%, about 20% and about 60%, about 20% and about 40%, about 20% and about 30%, about 30% and about 100%, about 30% and about 80%, about 30% and about 60%, about 30% and about 40%, about 40% and about 100%, about 40% and about 80%, about 40% and about 60%, about 60% and about 100%, about 60% and about 80%, or about 80% and about 100%.

Increased Stability of Nanoparticles Comprising Zinc Oxide Functionalized with Silane Compounds

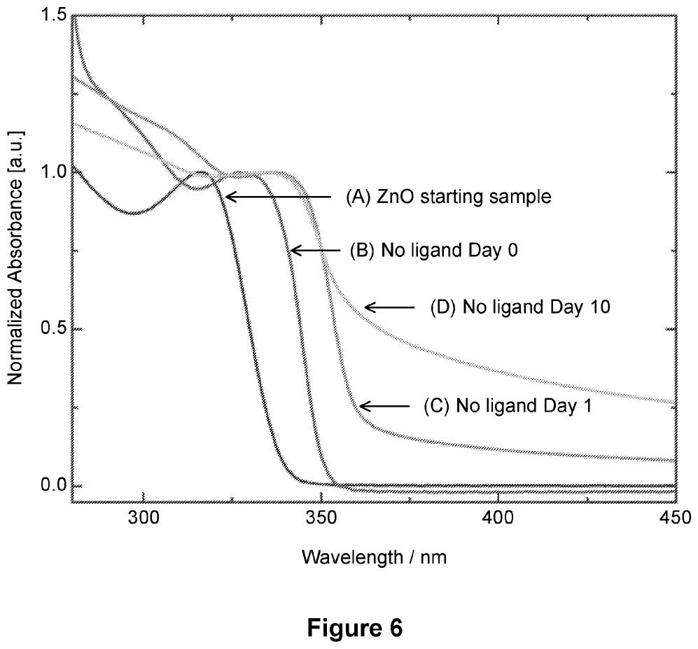

The silane compounds passivate the surface of the zinc oxide nanoparticles. As shown in FIG. 6, nanoparticles comprising zinc oxide passivated with silane compounds do not show a red shift in absorption spectra when stored at room temperature over several days. Nanoparticles comprising zinc oxide without silane treatment (and without ethanolamine treatment) red shifted significantly, and the nanoparticles eventually aggregated as shown by an increase in solution turbidity after one day and precipitation of a gel after three days.

Passivating the nanoparticles comprising zinc oxide with silane compounds provides increased stability and allows for storage of the nanoparticles for extended periods of time. In some embodiments, the nanoparticles comprising zinc oxide functionalized with silane compounds can be stored at a temperature between about 10° C. and about 90° C. for between about 1 minute and about 3 years, about 1 minute and about 12 months, about 1 minute and about 6 months, about 1 minute and about 3 months, about 1 minute and about 1 month, about 1 minute and about 15 days, about 1 minute and about 1 day, about 1 day and about 3 years, about 1 day and about 12 months, about 1 day and about 6 months, about 1 day and about 3 months, about 1 day and about 1 month, about 1 day and about 7 days, about 1 day and about 15 days, about 1 day and about 7 days, about 1 day and about 2 days, about 2 days and about 3 years, about 2 days and about 12 months, about 2 days and about 6 months, about 2 days and about 3 months, about 2 days and about 1 month, about 2 days and about 15 days, about 2 days and about 7 days, about 7 days and about 3 years, about 7 days and about 12 months, about 7 day and about 6 months, about 7 days and about 3 months, about 7 days and about 1 month, about 7 days and about 15 days, about 15 days and about 3 years, about 15 days and about 12 months, about 15 days and about 6 months, about 15 days and about 3 months, about 15 days and about 1 month, about 1 month and about 3 years, about 1 month and about 12 months, about 1 month and about 6 months, about 1 month and about 3 months, about 3 months and about 3 years, about 3 months and about 12 months, about 3 months and about 6 months, about 6 months and about 3 years, about 6 months and about 12 months, or about 12 months and about 3 years.

Passivating the nanoparticles comprising zinc oxide with silane compounds provides increased stability and allows for storage of the nanoparticles for extended periods of time. In some embodiments, the nanoparticles comprising zinc oxide functionalized with silane compounds can be stored at a temperature between about 30° C. and about 90° C. for between about 1 minute and about 3 years, about 1 minute and about 12 months, about 1 minute and about 6 months, about 1 minute and about 3 months, about 1 minute and about 1 month, about 1 minute and about 15 days, about 1 minute and about 1 day, about 1 day and about 3 years, about 1 day and about 12 months, about 1 day and about 6 months, about 1 day and about 3 months, about 1 day and about 1 month, about 1 day and about 7 days, about 1 day and about 15 days, about 1 day and about 7 days, about 1 day and about 2 days, about 2 days and about 3 years, about 2 days and about 12 months, about 2 days and about 6 months, about 2 days and about 3 months, about 2 days and about 1 month, about 2 days and about 15 days, about 2 days and about 7 days, about 7 days and about 3 years, about 7 days and about 12 months, about 7 day and about 6 months, about 7 days and about 3 months, about 7 days and about 1 month, about 7 days and about 15 days, about 15 days and about 3 years, about 15 days and about 12 months, about 15 days and about 6 months, about 15 days and about 3 months, about 15 days and about 1 month, about 1 month and about 3 years, about 1 month and about 12 months, about 1 month and about 6 months, about 1 month and about 3 months, about 3 months and about 3 years, about 3 months and about 12 months, about 3 months and about 6 months, about 6 months and about 3 years, about 6 months and about 12 months, or about 12 months and about 3 years.

In some embodiments, the nanoparticles comprising zinc oxide functionalized with silane compounds can be stored at room temperature (20° C. to 25° C.) for between about 1 minute and about 3 years, about 1 minute and about 12 months, about 1 minute and about 6 months, about 1 minute and about 3 months, about 1 minute and about 1 month, about 1 minute and about 15 days, about 1 minute and about 1 day, about 1 day and about 3 years, about 1 day and about 12 months, about 1 day and about 6 months, about 1 day and about 3 months, about 1 day and about 1 month, about 1 day and about 7 days, about 1 day and about 15 days, about 1 day and about 7 days, about 1 day and about 2 days, about 2 days and about 3 years, about 2 days and about 12 months, about 2 days and about 6 months, about 2 days and about 3 months, about 2 days and about 1 month, about 2 days and about 15 days, about 2 days and about 7 days, about 7 days and about 3 years, about 7 days and about 12 months, about 7 day and about 6 months, about 7 days and about 3 months, about 7 days and about 1 month, about 7 days and about 15 days, about 15 days and about 3 years, about 15 days and about 12 months, about 15 days and about 6 months, about 15 days and about 3 months, about 15 days and about 1 month, about 1 month and about 3 years, about 1 month and about 12 months, about 1 month and about 6 months, about 1 month and about 3 months, about 3 months and about 3 years, about 3 months and about 12 months, about 3 months and about 6 months, about 6 months and about 3 years, about 6 months and about 12 months, or about 12 months and about 3 years. In some embodiments, nanoparticles comprising zinc oxide functionalized with silane compounds can be stably stored at room temperature for at least 24 hours. In some embodiments, nanoparticles comprising zinc oxide functionalized with silane compounds can be stably stored at room temperature for at least 7 days. In some embodiments, nanoparticles comprising zinc oxide functionalized with silane compounds can be stably stored at room temperature for at least 14 days. In some embodiments, nanoparticles comprising zinc oxide functionalized with silane compounds can be stably stored at room temperature for at least 1 month.

### Emitting Layer

Sandwiched between the first transport layer and the second transport layer is an emitting layer that comprises at least one population of nanostructures. The emitting layer can be formed by depositing an admixture of at least one population of nanostructures and a solvent and allowing the solvent to evaporate. In some embodiments, the solvent evaporates at room temperature. In some embodiments, heat is applied to the deposited film to hasten the evaporation of the solvent. In some embodiments, the admixture of nanostructures and solvent is deposited using a spin-coating technique. In some embodiments, the thickness of the emitting layer is between about 10 nm and about 50 nm.

In some embodiments, the emitting layer comprises at least one nanostructure. In some embodiments, the emitting layer comprises 1, 2, 3, 4, or 5 nanostructures. In some embodiments, the emitting layer comprises 1 nanostructure. In some embodiments, the emitting layer comprises 2 nanostructures.

The quantum dots (or other nanostructures) for use in the present invention can be produced from any suitable material, suitably an inorganic material, and more suitably an inorganic conductive or semiconductive material. Suitable semiconductor materials include any type of semiconductor, including Group II-VI, Group III-V, Group IV-VI, and Group IV semiconductors. Suitable semiconductor materials include, but are not limited to, Si, Ge, Sn, Se, Te, B, C (including diamond), P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO₃ and combinations thereof.

The synthesis of Group II-VI nanostructures has been described in U.S. Pat. Nos. 6,225,198, 6,322,901, 6,207,229, 6,607,829, 6,861,155, 7,060,243, 7,125,605, 7,374,824, 7,566,476, 8,101,234, and 8,158,193 and in U.S. Patent Appl. Publication Nos. 2011/0262752 and 2011/0263062. In some embodiments, the core is a Group II-VI nanocrystal selected from the group consisting of ZnO, ZnSe, ZnS, ZnTe, CdO, CdSe, CdS, CdTe, HgO, HgSe, HgS, and HgTe. In some embodiments, the core is a nanocrystal selected from the group consisting of ZnSe, ZnS, CdSe, and CdS.

Although Group II-VI nanostructures such as CdSe and CdS quantum dots can exhibit desirable luminescence behavior, issues such as the toxicity of cadmium limit the applications for which such nanostructures can be used. Less toxic alternatives with favorable luminescence properties are thus highly desirable. Group III-V nanostructures in general and InP-based nanostructures in particular, offer the best known substitute for cadmium-based materials due to their compatible emission range.

In some embodiments, the nanostructures are free from cadmium. As used herein, the term “free of cadmium” is intended that the nanostructures contain less than 100 ppm by weight of cadmium. The Restriction of Hazardous Substances (RoHS) compliance definition requires that there must be no more than 0.01% (100 ppm) by weight of cadmium in the raw homogeneous precursor materials. The cadmium level in the Cd-free nanostructures is limited by the trace metal concentration in the precursor materials. The trace metal (including cadmium) concentration in the precursor materials for the Cd-free nanostructures, can be measured by inductively coupled plasma mass spectroscopy (ICP-MS) analysis, and are on the parts per billion (ppb) level. In some embodiments, nanostructures that are “free of cadmium” contain less than about 50 ppm, less than about 20 ppm, less than about 10 ppm, or less than about 1 ppm of cadmium.

In some embodiments, the core is a Group III-V nanostructure. In some embodiments, the core is a Group III-V nanocrystal selected from the group consisting of BN, BP, BAs, BSb, AlN, AlP, AlAs, AlSb, GaN, GaP, GaAs, GaSb, InN, InP, InAs, and InSb. In some embodiments, the core is an InP nanocrystal.

The synthesis of Group III-V nanostructures has been described in U.S. Pat. Nos. 5,505,928, 6,306,736, 6,576,291, 6,788,453, 6,821,337, 7,138,098, 7,557,028, 7,645,397, 8,062,967, and 8,282,412 and in U.S. Patent Appl. Publication No. 2015/0236195. Synthesis of Group III-V nanostructures has also been described in Wells, R. L., et al., “The use of tris(trimethylsilyl)arsine to prepare gallium arsenide and indium arsenide,” Chem. Mater. 1:4-6 (1989) and in Guzelian, A. A., et al., “Colloidal chemical synthesis and characterization of InAs nanocrystal quantum dots,” Appl. Phys. Lett. 69: 1432-1434 (1996).

Synthesis of InP-based nanostructures has been described, e.g., in Xie, R., et al., “Colloidal InP nanocrystals as efficient emitters covering blue to near-infrared,” J. Am. Chem. Soc. 129:15432-15433 (2007); Micic, O. I., et al., “Core-shell quantum dots of lattice-matched ZnCdSe₂ shells on InP cores: Experiment and theory,” J. Phys. Chem. B 104:12149-12156 (2000); Liu, Z., et al., “Coreduction colloidal synthesis of III-V nanocrystals: The case of InP,” Angew. Chem. Int. Ed. Engl. 47:3540-3542 (2008); Li, L. et al., “Economic synthesis of high quality InP nanocrystals using calcium phosphide as the phosphorus precursor,” Chem. Mater. 20:2621-2623 (2008); D. Battaglia and X. Peng, “Formation of high quality InP and InAs nanocrystals in a noncoordinating solvent,” Nano Letters 2:1027-1030 (2002); Kim, S., et al., “Highly luminescent InP/GaP/ZnS nanocrystals and their application to white light-emitting diodes,” J. Am. Chem. Soc. 134:3804-3809 (2012); Nann, T., et al., “Water splitting by visible light: A nanophotocathode for hydrogen production,” Angew. Chem. Int. Ed. 49:1574-1577 (2010); Borchert, H., et al., “Investigation of ZnS passivated InP nanocrystals by XPS,” Nano Letters 2:151-154 (2002); L. Li and P. Reiss, “One-pot synthesis of highly luminescent InP/ZnS nanocrystals without precursor injection,” J. Am. Chem. Soc. 130:11588-11589 (2008); Hussain, S., et al. “One-pot fabrication of high-quality InP/ZnS (core/shell) quantum dots and their application to cellular imaging,” Chemphyschem. 10:1466-1470 (2009); Xu, S., et al., “Rapid synthesis of high-quality InP nanocrystals,” J. Am. Chem. Soc. 128:1054-1055 (2006); Micic, O. I., et al., “Size-dependent spectroscopy of InP quantum dots,” J. Phys. Chem. B 101:4904-4912 (1997); Haubold, S., et al., “Strongly luminescent InP/ZnS core-shell nanoparticles,” Chemphyschem. 5:331-334 (2001); CrosGagneux, A., et al., “Surface chemistry of InP quantum dots: A comprehensive study,” J. Am. Chem. Soc. 132:18147-18157 (2010); Micic, O. I., et al., “Synthesis and characterization of InP, GaP, and GaInP₂ quantum dots,” J. Phys. Chem. 99:7754-7759 (1995); Guzelian, A. A., et al., “Synthesis of size-selected, surface-passivated InP nanocrystals,” J. Phys. Chem. 100:7212-7219 (1996); Lucey, D. W., et al., “Monodispersed InP quantum dots prepared by colloidal chemistry in a non-coordinating solvent,” Chem. Mater. 17:3754-3762 (2005); Lim, J., et al., “InP@ZnSeS, core@composition gradient shell quantum dots with enhanced stability,” Chem. Mater. 23:4459-4463 (2011); and Zan, F., et al., “Experimental studies on blinking behavior of single InP/ZnS quantum dots: Effects of synthetic conditions and UV irradiation,” J. Phys. Chem. C 116:394-3950 (2012).

In some embodiments, the core is doped. In some embodiments, the dopant of the nanocrystal core comprises a metal ion, including one or more transition metal ions. In some embodiments, the dopant is a transition metal ion selected from the group consisting of Ti, Zr, Hf, V, Nb, Ta, Cr, Mo, W, Mn, Tc, Re, Fe, Ru, Os, Co, Rh, Ir, Ni, Pd, Pt, Cu, Ag, Au, and combinations thereof. In some embodiments, the dopant comprises a non-metal. In some embodiments, the dopant is ZnS, ZnSe, ZnTe, CdSe, CdS, CdTe, HgS, HgSe, HgTe, CuInS₂, CuInSe₂, AlN, AlP, AlAs, GaN, GaP, or GaAs.

Inorganic shell coatings on nanostructures are a universal approach to tailoring their electronic structure. Additionally, deposition of an inorganic shell can produce more robust particles by passivation of surface defects. Ziegler, J., et al., Adv. Mater. 20:4068-4073 (2008). For example, shells of wider band gap semiconductor materials such as ZnS can be deposited on a core with a narrower band gap—such as CdSe or InP—to afford structures in which excitons are confined within the core. This approach increases the probability of radiative recombination and makes it possible to synthesize very efficient quantum dots with quantum yields close to unity and thin shell coatings.

In some embodiments, the nanostructures include a core and at least one shell. In some embodiments, the nanostructures include a core and at least two shells. The shell can, e.g., increase the quantum yield and/or stability of the nanostructures. In some embodiments, the core and the shell comprise different materials. In some embodiments, the nanostructure comprises shells of different shell material.

Exemplary materials for preparing shells include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, GaSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO, and combinations thereof.

In some embodiments, the shell is a mixture of at least two of a zinc source, a selenium source, a sulfur source, a tellurium source, and a cadmium source. In some embodiments, the shell is a mixture of two of a zinc source, a selenium source, a sulfur source, a tellurium source, and a cadmium source. In some embodiments, the shell is a mixture of three of a zinc source, a selenium source, a sulfur source, a tellurium source, and a cadmium source. In some embodiments, the shell is a mixture of: zinc and sulfur; zinc and selenium; zinc, sulfur, and selenium; zinc and tellurium; zinc, tellurium, and sulfur; zinc, tellurium, and selenium; zinc, cadmium, and sulfur; zinc, cadmium, and selenium; cadmium and sulfur; cadmium and selenium; cadmium, selenium, and sulfur; cadmium and zinc; cadmium, zinc, and sulfur; cadmium, zinc, and selenium; or cadmium, zinc, sulfur, and selenium. In some embodiments, the shell is a mixture of zinc and selenium. In some embodiments, the shell is a mixture of zinc and sulfur.

Exemplary core/shell luminescent nanostructures include, but are not limited to (represented as core/shell) CdSe/ZnS, InP/ZnS, PbSe/PbS, CdSe/CdS, CdTe/CdS, and CdTe/ZnS. The synthesis of core/shell nanostructures is disclosed in U.S. Pat. No. 9,169,435.

In some embodiments, the nanostructures include a core and at least two shells. In some embodiments, one shell is a mixture of zinc and selenium and one shell is a mixture of zinc and sulfur. In some embodiments, the core/shell/shell nanostructure is InP/ZnSe/ZnS.

The luminescent nanocrystals can be made from a material impervious to oxygen, thereby simplifying oxygen barrier requirements and photostabilization of the quantum dots in the quantum dot film layer. In exemplary embodiments, the luminescent nanocrystals are coated with one or more organic polymeric ligand material and dispersed in an organic polymeric matrix comprising one or more matrix materials. The luminescent nanocrystals can be further coated with one or more inorganic layers comprising one or more material such as a silicon oxide, an aluminum oxide, or a titanium oxide (e.g., Sift, Si₂O₃, TiO₂, or Al₂O₃), to hermetically seal the quantum dots.

Illumination Devices with Improved Properties

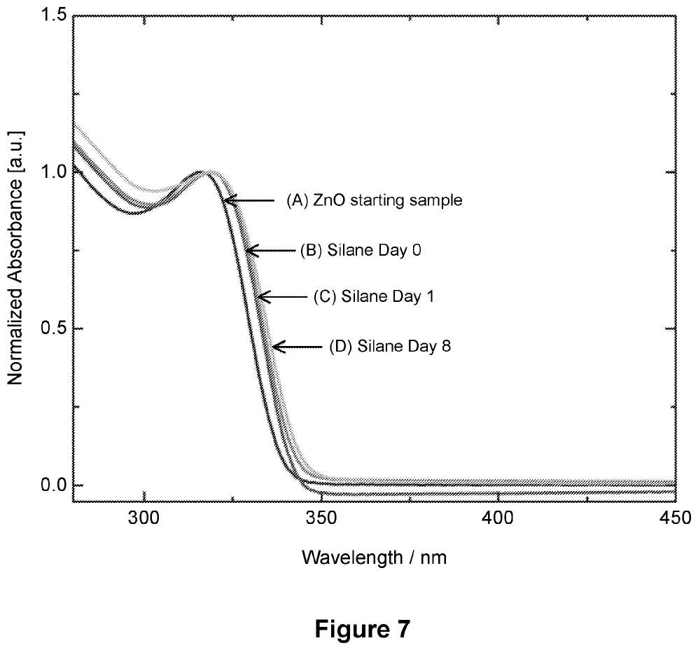

As shown in FIG. 7, red-emitting quantum dot light emitting diodes (QD-LEDs) prepared using nanoparticles comprising zinc oxide functionalized with silane compounds show much less change in device external quantum efficiency (EQE) after 3 and 7 days of storage than devices prepared with ethanolamine functionalized ZnMgO nanoparticles. And, devices prepared with ZnMgO nanoparticles without added ligand showed a similar change in EQE over time to devices prepared with silane functionalized zinc oxide nanoparticles. But, devices prepared with ZnMgO nanoparticles without added ligand showed a lower maximum EQE than devices prepared with silane functionalized zinc oxide nanoparticles.

In contrast to blue-emitting QD-LEDs, the EQE of red-light emitting QD-LEDs increases with the aging of the ZnMgO nanoparticles. But, for consistent process it would be desirable to have the best performance right away without subsequent changes in any direction. It is also noteworthy that treatment with silane compounds does not negatively affect device performance in terms of reachable efficiency or luminance.

In some embodiments, illumination devices prepared using nanoparticles comprising zinc oxide functionalized with silane compounds provide increased stability and allows for storage of the illumination device for extended periods of time. In some embodiments, devices comprising nanoparticles comprising zinc oxide functionalized with silane compounds can be stored at a temperature between about 10° C. and about 90° C. for between about 1 minute and about 3 years, about 1 minute and about 12 months, about 1 minute and about 6 months, about 1 minute and about 3 months, about 1 minute and about 1 month, about 1 minute and about 15 days, about 1 minute and about 1 day, about 1 day and about 3 years, about 1 day and about 12 months, about 1 day and about 6 months, about 1 day and about 3 months, about 1 day and about 1 month, about 1 day and about 7 days, about 1 day and about 15 days, about 1 day and about 7 days, about 1 day and about 2 days, about 2 days and about 3 years, about 2 days and about 12 months, about 2 days and about 6 months, about 2 days and about 3 months, about 2 days and about 1 month, about 2 days and about 15 days, about 2 days and about 7 days, about 7 days and about 3 years, about 7 days and about 12 months, about 7 day and about 6 months, about 7 days and about 3 months, about 7 days and about 1 month, about 7 days and about 15 days, about 15 days and about 3 years, about 15 days and about 12 months, about 15 days and about 6 months, about 15 days and about 3 months, about 15 days and about 1 month, about 1 month and about 3 years, about 1 month and about 12 months, about 1 month and about 6 months, about 1 month and about 3 months, about 3 months and about 3 years, about 3 months and about 12 months, about 3 months and about 6 months, about 6 months and about 3 years, about 6 months and about 12 months, or about 12 months and about 3 years.

In some embodiments, devices comprising nanoparticles comprising zinc oxide functionalized with silane compounds can be stored at a temperature between about 30° C. and about 90° C. for between about 1 minute and about 3 years, about 1 minute and about 12 months, about 1 minute and about 6 months, about 1 minute and about 3 months, about 1 minute and about 1 month, about 1 minute and about 15 days, about 1 minute and about 1 day, about 1 day and about 3 years, about 1 day and about 12 months, about 1 day and about 6 months, about 1 day and about 3 months, about 1 day and about 1 month, about 1 day and about 7 days, about 1 day and about 15 days, about 1 day and about 7 days, about 1 day and about 2 days, about 2 days and about 3 years, about 2 days and about 12 months, about 2 days and about 6 months, about 2 days and about 3 months, about 2 days and about 1 month, about 2 days and about 15 days, about 2 days and about 7 days, about 7 days and about 3 years, about 7 days and about 12 months, about 7 day and about 6 months, about 7 days and about 3 months, about 7 days and about 1 month, about 7 days and about 15 days, about 15 days and about 3 years, about 15 days and about 12 months, about 15 days and about 6 months, about 15 days and about 3 months, about 15 days and about 1 month, about 1 month and about 3 years, about 1 month and about 12 months, about 1 month and about 6 months, about 1 month and about 3 months, about 3 months and about 3 years, about 3 months and about 12 months, about 3 months and about 6 months, about 6 months and about 3 years, about 6 months and about 12 months, or about 12 months and about 3 years.

In some embodiments, devices comprising nanoparticles comprising zinc oxide functionalized with silane compounds can be stored at room temperature (20° C. to 25° C.) for between about 1 minute and about 3 years, about 1 minute and about 12 months, about 1 minute and about 6 months, about 1 minute and about 3 months, about 1 minute and about 1 month, about 1 minute and about 15 days, about 1 minute and about 1 day, about 1 day and about 3 years, about 1 day and about 12 months, about 1 day and about 6 months, about 1 day and about 3 months, about 1 day and about 1 month, about 1 day and about 7 days, about 1 day and about 15 days, about 1 day and about 7 days, about 1 day and about 2 days, about 2 days and about 3 years, about 2 days and about 12 months, about 2 days and about 6 months, about 2 days and about 3 months, about 2 days and about 1 month, about 2 days and about 15 days, about 2 days and about 7 days, about 7 days and about 3 years, about 7 days and about 12 months, about 7 day and about 6 months, about 7 days and about 3 months, about 7 days and about 1 month, about 7 days and about 15 days, about 15 days and about 3 years, about 15 days and about 12 months, about 15 days and about 6 months, about 15 days and about 3 months, about 15 days and about 1 month, about 1 month and about 3 years, about 1 month and about 12 months, about 1 month and about 6 months, about 1 month and about 3 months, about 3 months and about 3 years, about 3 months and about 12 months, about 3 months and about 6 months, about 6 months and about 3 years, about 6 months and about 12 months, or about 12 months and about 3 years. In some embodiments, devices comprising nanoparticles comprising zinc oxide functionalized with silane compounds can be stably stored at room temperature for at least 24 hours. In some embodiments, devices comprising nanoparticles comprising zinc oxide functionalized with silane compounds can be stably stored at room temperature for at least 7 days. In some embodiments, devices comprising nanoparticles comprising zinc oxide functionalized with silane compounds can be stably stored at room temperature for at least 14 days. In some embodiments, devices comprising nanoparticles comprising zinc oxide functionalized with silane compounds can be stably stored at room temperature for at least 1 month.

In some embodiments, an illumination device prepared using nanoparticles comprising zinc oxide functionalized with silane compounds shows an EQE of between about 1.5% and about 20%, about 1.5% and about 15%, about 1.5% and about 12%, about 1.5% and about 10%, about 1.5% and about 8%, about 1.5% and about 4%, about 1.5% and about 3%, about 3% and about 20%, about 3% and about 15%, about 3% and about 12%, about 3% and about 10%, about 3% and about 8%, about 8% and about 20%, about 8% and about 15%, about 8% and about 12%, about 8% and about 10%, about 10% and about 20%, about 10% and about 15%, about 10% and about 12%, about 12% and about 20%, about 12% and about 15%, or about 15% and about 20%. In some embodiments, the illumination device is a light emitting diode.

The following examples are illustrative and non-limiting, of the products and methods described herein. Suitable modifications and adaptations of the variety of conditions, formulations, and other parameters normally encountered in the field and which are obvious to those skilled in the art in view of this disclosure are within the spirit and scope of the invention.

### EXAMPLES

The following examples are illustrative and non-limiting, of the products and methods described herein. Suitable modifications and adaptations of the variety of conditions, formulations, and other parameters normally encountered in the field and which are obvious to those skilled in the art in view of this disclosure are within the spirit and scope of the invention.

### Example 1

### Preparation of Silane-Treated ZnO Nanoparticles

Zinc acetate dihydrate (7.0 mmol, 1.54 g) was dissolved in dimethyl sulfoxide (70 mL) by stirring at room temperature. Separately, tetramethylammonium hydroxide pentahydrate (TMAH, 6.4 mmol, 1.17 g) was dissolved in ethanol (16.7 ml). The TMAH solution was added dropwise to the zinc acetate solution over a period of 90 seconds. The reaction mixture was stirred at room temperature for 20 minutes. Then a solution of trimethoxymethylsilane (3.9 mmol, 0.53 g) in ethanol (10 mL) was added quickly. The resulting mixture was stirred at room temperature for 100 minutes. The silane-treated ZnO nanoparticles were isolated and purified by precipitation with a mixture of ethyl acetate and hexane (1:1, 300 mL), centrifugation, decantation of the supernatant, redispersion of the precipitated nanoparticles in ethanol (20 mL), precipitation with hexane (40 mL), and redispersion in ethanol (6 mL).

### Example 2

### Preparation of Ethanolamine-Treated ZnMgO Nanoparticles

Zinc acetate dihydrate (6.0 mmol, 1.31 g) and magnesium acetate tetrahydrate (1.0 mmol, 0.23 g) were dissolved in dimethyl sulfoxide (70 mL) by stirring at room temperature. Separately, TMAH (6.4 mmol, 1.17 g) was dissolved in ethanol (16.7 mL). The TMAH solution was added dropwise to the zinc acetate solution over a period of 90 seconds. The reaction mixture was stirred at room temperature for 20 minutes. The ZnMgO nanoparticles were isolated by precipitation with ethyl acetate (400 mL), centrifugation, decantation of the supernatant, and redispersion of the precipitated nanoparticles in ethanol (20 mL). Then 2-ethanolamine (0.47 mL) was added to the ZnMgO nanoparticle solution. The nanoparticles were purified by precipitation with a mixture of ethyl acetate and hexane (1:1, 400 mL), centrifugation, decantation of the supernatant, and redispersion in ethanol (6 mL).

### Example 3

Preparation of a QD-LED with Silane-Treated ZnO Nanoparticles.

A light emitting device was prepared using a combination of spin-coating and thermal evaporation to form the device layers. First, a poly(3,4-ethylenedioxythiophene):poly(styrene) (PEDOT:PSS) hole injection layer was spin-coated to a thickness of about 50 nm onto a UV-ozone-treated indium tin oxide (ITO) substrate and baked for 15 minutes at 200° C. The device was transferred to an inert atmosphere and a poly[(9,9-dioctylfluorenyl-2,7-diyl)-co-(4,4′-(N-(4-sec-butylphenyl)diphenylamine)] (TFB) hole transport material was then deposited by spin-coating to a final thickness of about 20 nm and baked at 135° C. for 20 minutes. One monolayer of InP/ZnSe/ZnS quantum dots were then deposited by spin-coating from a solution of 9 mg/mL octane. The quantum dots used in this device include a 3-4 nm InP core with a nominal shell composition of 6.5 monolayers (ML) ZnSe and 3 ML ZnS. After the deposition of the quantum dot layer, a silane-treated ZnMgO electron transport layer was deposited by spin-coating to a final thickness of about 60 nm from a solution of colloidal nanocrystals. An aluminum cathode was then deposited by thermal evaporation to a final thickness of about 150 nm, and the device was encapsulated using a cap-glass, getter, and epoxy resin.

### Example 4

Preparation of Device with Ethanolamine-Treated ZnMgO Nanoparticles.

A light emitting device was prepared using a combination of spin-coating and thermal evaporation to form the device layers. First, a poly(3,4-ethylenedioxythiophene):poly(styrene) (PEDOT:PSS) hole injection layer was spin-coated to a thickness of about 50 nm onto a UV-ozone-treated indium tin oxide (ITO) substrate and baked for 15 minutes at 200° C. The device was transferred to an inert atmosphere and a poly[(9,9-dioctylfluorenyl-2,7-diyl)-co-(4,4′-(N-(4-sec-butylphenyl)diphenylamine)] (TFB) hole transport material was then deposited by spin-coating to a final thickness of about 20 nm and baked at 135° C. for 20 minutes. One monolayer of InP/ZnSe/ZnS quantum dots were then deposited by spin-coating from a solution of 9 mg/mL octane. The quantum dots used in this device include a 3-4 nm InP core with a nominal shell composition of 6.5 monolayers (ML) ZnSe and 3 ML ZnS. After the deposition of the quantum dot layer, an ethanolamine-treated ZnMgO electron transport layer was deposited by spin-coating to a final thickness of about 60 nm from a solution of colloidal nanocrystals. An aluminum cathode was then deposited by thermal evaporation to a final thickness of about 150 nm, and the device was encapsulated using a cap-glass, getter, and epoxy resin.

### Example 5

### Analysis of Electroluminescent Devices Prepared Using the Nanostructures

FIG. 7 shows maximum external quantum efficiency measurements for quantum dot light emitting devices prepared using ethanolamine-treated ZnMgO, untreated ZnMgO, and silane-treated ZnMgO nanoparticles in the electron transport layer after storage for 2 and 7 days. As shown in FIG. 7, quantum dot light emitting devices prepared using silane-treated ZnMgO nanoparticles in the electron transport layer showed a greater maximum external quantum efficiency than devices prepared with ethanolamine-treated ZnMgO in the electron transport layer and devices prepared comprising ZnMgO with no ligand.

While various embodiments have been described above, it should be understood that they have been presented by way of example only, and not limitation. It will be apparent to persons skilled in the relevant art that various changes in form and detail can be made therein without departing from the spirit and scope of the invention. Thus, the breadth and scope should not be limited by any of the above-described exemplary embodiments, but should be defined only in accordance with the following claims and their equivalents.

All publications, patents and patent applications mentioned in this specification are indicative of the level of skill of those skilled in the art to which this invention pertains, and are herein incorporated by reference to the same extent as if each individual publication, patent or patent application was specifically and individually indicated to be incorporated by reference.

1. A nanoparticle composition, comprising:
(a) at least one population of nanoparticles comprising a zinc oxide; and
(b) at least one silane compound bound to the surface of the nanoparticles;
wherein the nanostructure composition is stable for at least 7 days when stored at room temperature.

2.-3. (canceled)

4. The nanoparticle composition of claim 1, wherein the nanoparticles comprising a zinc oxide are alloyed with at least one metal ion.

5. The nanoparticle composition of claim 4, wherein the nanoparticles comprising a zinc oxide are alloyed with magnesium.

6. The nanoparticle composition of claim 1, wherein the at least one silane compound has the formula: 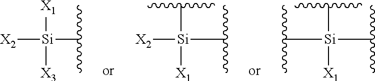
wherein:
X₁ is straight or branched C₁₋₂₀ alkyl;
X₂ is straight or branched C₁₋₂₀ alkyl or straight or branched C₁₋₂₀ alkoxy; and
X₃ is straight or branched C₁₋₂₀ alkyl or straight or branched C₁₋₂₀ alkoxy;
wherein at least one of X₁, X₂, and X₃ is a straight or branched C₁₋₂₀ alkyl.

7. The nanoparticle composition of claim 6, wherein X₁ is a straight C₁₋₂₀ alkyl and X₂ and X₃ are straight C₁₋₂₀ alkoxy.

8. The nanoparticle composition of claim 6, wherein X₁ and X₂ are straight C₁₋₂₀ alkyl and X₃ is a straight C₁₋₂₀ alkoxy.

9. The nanoparticle composition of claim 6, wherein the at least one silane compound is selected from the group consisting of dimethoxymethylsilyl-, diethoxymethylsilyl-, dipropoxymethylsilyl-, dibutoxymethylsilyl-, methoxydimethylsilyl-, ethoxydimethylsilyl-, dimethoxydodecylsilyl-, methoxydodecylmethylsilyl-, dimethoxyhexadecylsilyl-, dimethoxyoctadecylsilyl-, dimethoxy(n-octyl)silyl-, diethoxy(n-octyl)silyl-, ethoxyoctylmethylsilyl-, dimethoxypropylsilyl-, diethoxypropylsilyl-, dimethoxy(n-butyl)silyl-, diethoxy(n-butyl)silyl-, dimethoxy(i-butyl)silyl-, and diethoxy(i-butyl)silyl-.

10. The nanoparticle composition of claim 6, wherein the at least one silane compound is dimethoxymethylsilyl-.

11.-12. (canceled)

13. An illumination device comprising the nanoparticle composition of claim 1.

14. (canceled)

15. A method of preparing the nanoparticle composition of claim 1, the method comprising:
(a) admixing a reaction mixture comprising a population of nanoparticles comprising a zinc oxide having at least one hydroxy group covalently bound to the nanoparticle with at least one silane; and
(b) adding a reactant comprising water, a base, or a combination thereof to the reaction mixture in (a).

16. The method of claim 15, wherein the nanoparticles comprising a zinc oxide are doped with at least one dopant.

17. (canceled)

18. The method of claim 15, wherein the nanoparticles comprising a zinc oxide are alloyed with at least one metal ion.

19. The method of claim 18, wherein the nanoparticles comprising a zinc oxide are alloyed with magnesium ion.

20. The method of claim 15, wherein the at least one silane has the formula: 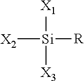
wherein:
R is a straight or branched C₁₋₂₀ alkoxy;
X₁ is straight or branched C₁₋₂₀ alkyl or straight or branched C₁₋₂₀ alkoxy;
X₂ is straight or branched C₁₋₂₀ alkyl or straight or branched C₁₋₂₀ alkoxy; and
X₃ is straight or branched C₁₋₂₀ alkyl or straight or branched C₁₋₂₀ alkoxy;
wherein at least one of X₁, X₂, and X₃ is a straight or branched C₁₋₂₀ alkyl.

21. The method of claim 20, wherein X₁ is a straight C₁₋₂₀ alkyl and X₂ and X₃ are straight C₁₋₂₀ alkoxy.

22. The method of claim 20, wherein X₁ and X₂ are straight C₁₋₂₀ alkyl and X₃ is a straight C₁₋₂₀ alkoxy.

23. The method of claim 20, wherein the at least one silane is selected from the group consisting of trimethoxymethylsilane, triethoxymethylsilane, tripropoxymethylsilane, tributoxymethylsilane, dimethoxydimethylsilane, diethoxydimethylsilane, trimethoxydodecylsilane, dimethoxydodecylmethylsilane, trimethoxyhexadecylsilane, trimethoxyoctadecylsilane, trimethoxy(n-octyl)silane, triethoxy(n-octyl)silane, diethoxyoctylmethylsilane, trimethoxypropylsilane, triethoxypropylsilane, trimethoxy(n-butyl)silane, triethoxy(n-butyl)silane, trimethoxy(i-butyl)silane, and triethoxy(i-butyl)silane.

24. The method of claim 20, wherein the at least one silane is trimethoxymethylsilane.

25.-39. (canceled)

40. An illumination device comprising:
(a) an electron transport layer, wherein the electron transport layer comprises the nanoparticle composition of claim 1; and
(b) an emitting layer, wherein the emitting layer comprises at least one population of nanostructures.

41.-57. (canceled)

58. An illumination device comprising:
(a) a first conductive layer;
(b) a second conductive layer; and
(c) an electron transport layer, wherein the electron transport layer comprises the nanoparticle composition of claim 1.

59.-86. (canceled)
